(19) United States
(12) Patent Application Publication
(10) Pub. No.: US 2024/0388265 A1
(43) Pub. Date: Nov. 21, 2024

(54) Wideband Radio Frequency Amplifier Using Cross-Over Diplexers

(71) Applicant: Wilson Electronics, LLC, St. George, UT (US)

(72) Inventors: Ken Trayling, London (GB); Chris Potter, Fulbourn (GB); Stephen Harris, Basingstoke (GB); Ian Rossuck, Saffron Walden (GB); James A. Martin, Jr., Midland, TX (US); Christopher Ken Ashworth, Toquerville, UT (US)

(21) Appl. No.: 18/204,222

(22) Filed: May 31, 2023

Related U.S. Application Data
(60) Provisional application No. 63/467,890, filed on May 19, 2023.

(51) Int. Cl. H03F 3/24; H04B 1/04

(52) U.S. Cl. CPC H03F 3/245; H04B 1/04; H03F 2200/451

(57) ABSTRACT

A technology is described for a wide-band radio frequency amplifier using cross-over diplexers. A first port is configured to receive RF signals in a wide-band RF spectrum. A cross-over diplexer splitter is coupled to the first port. The cross-over diplexer splitter is configured to filter the RF signals in the wide-band RF spectrum into a low frequency (LF) signal having an LF pass-band and a high frequency (HF) signal having an HF pass-band with the LF pass-band crossing the HF pass-band at a cross-over frequency. An HF RF amplifier is configured to amplify the HF signal to form an amplified HF signal. An LF RF amplifier configured to amplify the LF signal to form an amplified LF signal. A cross-over diplexer combiner is configured to combine the amplified HF signal and the amplified LF signal and output amplified RF signals in the wide-band RF spectrum.

### RELATED APPLICATIONS

The present application claims the benefit of U.S. Provisional Patent Application No. 63/467,890, filed May 19, 2023 with a docket number of 3969-204.PROV, the entire specification of which is hereby incorporated by reference in its entirety for all purposes.

### BACKGROUND

Radio Frequency (RF) signal amplifiers are used in modern electronic devices, such as wireless communications devices, to drive a low-power RF signal to a higher-power RF signal. RF signal amplifiers are typically constructed using solid state electronics. One example of a solid-state RF signal amplifier is a metal-oxide-semiconductor field-effect-transistor (MOSFET).

An RF signal amplifier, such as a MOSFET, is typically designed to replicate a low power input RF signal with a higher power output RF signal that has similar amplitude and phase characteristics as the input RF signal over the pass-band of the RF signal. Significant changes in the phase and/or amplitude of portions of the signal in the pass-band relative to the rest of the signal in the pass-band can make the information carried on the RF signal difficult or impossible to detect.

RF signal amplifiers, such as MOSFETs, are non-linear devices that output different signal characteristics at different frequencies. An RF signal amplifier can be designed and constructed to have a relatively linear output over a selected frequency range. However, RF signal amplifiers that cover a frequency range greater than one octave can emit spurious harmonic signals due to the non-linearities of the amplifier. In addition, other solid-state power amplifier parameters, such as gain, power output, bandwidth, power efficiency, linearity, input and output impedance matching, and heat dissipation tend to degrade over wide bandwidths. Accordingly, there is an advantage to designing RF amplifiers that support less than an octave bandwidth.

### BRIEF DESCRIPTION OF THE DRAWINGS

Features and advantages of the disclosure will be apparent from the detailed description which follows, taken in conjunction with the accompanying drawings, which together illustrate, by way of example, features of the disclosure; and, wherein:

FIG. 1a illustrates a wide-band radio frequency (RF) repeater with cross-over diplexers in accordance with an example;

FIG. 1b illustrates a cross-over diplexer splitter in accordance with an example;

FIG. 1c illustrates a cross-over diplexer combiner in accordance with an example;

FIG. 1d illustrates a cross-over diplexer configured to attenuate harmonic signals with a low frequency pass-band and a high frequency pass-band with a cross-over frequency Fcross in accordance with an example;

FIG. 1e illustrates a cross-over diplexer configured to attenuate difference signals with a low frequency pass-band and a high frequency pass-band with a cross-over frequency Fcross in accordance with an example;

FIG. 2a illustrates a network analyzer diagram showing an LF signal and an HF signal communicated by a cross-over diplexer configured to split a wide-band RF input signal into contiguous sub-bands without guard bands in accordance with an example;

FIG. 2b illustrates a network analyzer diagram showing an LF signal and an HF signal communicated by a cross-over diplexer configured to split a wide-band RF input signal into sub-bands with guard bands in accordance with an example;

FIG. 3 illustrates a wide-band radio frequency (RF) repeater with cross-over diplexers and an amplitude and phase equalizer in accordance with an example;

FIG. 4 illustrates a wide-band radio frequency (RF) repeater with cross-over diplexers and a phase equalizer in accordance with an example;

FIG. 5 illustrates a wide-band radio frequency (RF) repeater with cross-over diplexers, an amplitude and phase equalizer, and a low-pass filter in accordance with an example;

FIG. 6 illustrates a wide-band radio frequency (RF) repeater with cross-over diplexers, an amplitude equalizer, and a separate low-pass filter and phase equalizer in accordance with an example;

FIG. 7 illustrates a wide-band radio frequency (RF) repeater with cross-over diplexers and a low-pass filter in accordance with an example;

FIG. 8 illustrates a wide-band radio frequency (RF) repeater with 2n+1 cross-over diplexers to divide the wide-band RF signal into 2n sub-bands in accordance with an example;

FIG. 9 illustrates a wide-band radio frequency (RF) repeater with a cross-over diplexer coupled to antennas in accordance with an example;

FIG. 10 illustrates a repeater in communication with a wireless device and a base station in accordance with an example;

FIG. 11 illustrates a repeater having a first direction amplification and filtering path and a second direction amplification and filtering path configured for one or more wide-band RF repeaters with cross-over diplexers in accordance with an example;

FIG. 12 illustrates a repeater coupled to an optical distributed antenna system configured for one or more wide-band RF repeaters with cross-over diplexers in accordance with an example; and

FIG. 13 illustrates a diagram of a wireless device in accordance with an example.

Reference will now be made to the exemplary embodiments illustrated, and specific language will be used herein to describe the same. It will nevertheless be understood that no limitation of the scope of the invention is thereby intended.

### DETAILED DESCRIPTION

Before the present invention is disclosed and described, it is to be understood that this invention is not limited to the particular structures, process steps, or materials disclosed herein, but is extended to equivalents thereof as would be recognized by those ordinarily skilled in the relevant arts. It should also be understood that terminology employed herein is used for the purpose of describing particular examples only and is not intended to be limiting. The same reference numerals in different drawings represent the same element. Numbers provided in flow charts and processes are provided for clarity in illustrating steps and operations and do not necessarily indicate a particular order or sequence.

### Definitions

In describing and claiming the present invention, the following terminology will be used.

As used herein, a “Radio Frequency (RF) signal” is an RF signal having a pass-band configured to carry information that is modulated onto the RF signal.

As used herein, a “cross-over diplexer” is a diplexer with an input port configured to receive RF signals over an RF spectrum, the cross-over diplexer comprising a first filter having a first pass-band configured to pass a first portion of the RF spectrum and a second filter having a second pass-band configured to pass a second portion of the RF spectrum, and the first filter and the second filter are designed to overlap at a cross over frequency that is approximately 3 dB below the signal power of the RF signal at the input port, such that approximately half of the RF signal power at the cross-over frequency is comprised of the first portion of the RF signal and approximately half of the RF signal power at the cross-over frequency is comprised of the second portion of the RF signal. Actual measurements can vary from the design due to signal losses, temperature variations, and imperfections in the design of the electronic components in the cross-over diplexer. A cross-over diplexer can be used as either a combiner or a splitter.

As used herein, a “wideband radio frequency amplifier using cross-over diplexers” is an amplifier configured to amplify RF signals over a wide RF spectrum, using cross-over diplexers, with a combined pass-band that is greater than one octave, and in some cases, greater than two octaves, or even n octaves, where n is a positive integer; the cross-over diplexers have similar operating characteristics over a wide pass-band, the similar operating characteristics including a change in amplitude over the wide pass-band of less than 3 decibels, and in some embodiments less than 4 decibels (dB).

As used herein, a “guard band” is an unused part of the radio spectrum between radio frequency signal bands, for the purpose of preventing interference or isolating one band from another band.

The singular forms “a,” “an,” and “the” include plural referents unless the context clearly dictates otherwise. Thus, for example, reference to “an RF amplifier” includes reference to one or more of such structures and reference to “amplifying” refers to one or more of such operations.

As used herein with respect to an identified property or circumstance, “substantially” refers to a degree of deviation that is sufficiently small so as to not measurably detract from the identified property or circumstance. The exact degree of deviation allowable may in some cases depend on the specific context.

The use of “substantially” is equally applicable when used in a negative connotation to refer to the complete or near complete lack of an action, characteristic, property, state, structure, item, or result.

As used herein, “adjacent” refers to the proximity of two structures or elements. Particularly, elements that are identified as being “adjacent” may be either abutting or connected. Such elements may also be near or close to each other without necessarily contacting each other. The exact degree of proximity may in some cases depend on the specific context.

As used herein, the term “about” is used to provide flexibility and imprecision associated with a given term, metric or value. The degree of flexibility for a particular variable can be readily determined by one skilled in the art. However, unless otherwise enunciated, the term “about” generally connotes flexibility of less than 2%, and most often less than 1%, and in some cases less than 0.01%.

As used herein, comparative terms such as “increased,” “decreased,” “better,” “worse,” “higher,” “lower,” “enhanced,” “improved,” “maximized,” “minimized,” and the like refer to a property of a device, component, composition, or activity that is measurably different from other devices, components, compositions, or activities that are in a surrounding or adjacent area, that are similarly situated, that are in a single device or composition or in multiple comparable devices or compositions, that are in a group or class, that are in multiple groups or classes, or as compared to an original or baseline state, or the known state of the art.

Reference in this specification may be made to devices, structures, systems, or methods that provide “improved” performance. It is to be understood that unless otherwise stated, such “improvement” is a measure of a benefit obtained based on a comparison to devices, structures, systems, or methods in the prior art. Furthermore, it is to be understood that the degree of improved performance may vary between disclosed embodiments and that no equality or consistency in the amount, degree, or realization of improved performance is to be assumed as universally applicable.

In this disclosure, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements that do not materially affect the basic and novel characteristics or function of the item(s) used in connection therewith. For example, trace elements present in a composition, but not affecting the compositions nature or characteristics would be permissible if present under the “consisting essentially of” language, even though not expressly recited in a list of items following such terminology. When using an open-ended term, like “comprising” or “including,” in the written description it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that any terms so used are interchangeable under appropriate circumstances such that the embodiments described herein are, for example, capable of operation in sequences other than those illustrated or otherwise described herein.

The term “coupled,” as used herein, is defined as directly or indirectly connected in a biological, chemical, mechanical, electrical, or nonelectrical manner. “Directly coupled” structures or elements are in contact with one another. In this written description, recitation of “coupled” or “connected” provides express support for “directly coupled” or “directly connected” and vice versa. “Communicatively coupled” structures or elements are indirectly in contact or communication with other structures or elements. Objects described herein as being “adjacent to” each other may be in physical contact with each other, in close proximity to each other, or in the same general region or area as each other, as appropriate for the context in which the phrase is used.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

As used herein, the term “at least one of” is intended to be synonymous with “one or more of.” For example, “at least one of A, B and C” explicitly includes only A, only B, only C, or combinations of each.

Numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a numerical range of about 1 to about 4.5 should be interpreted to include not only the explicitly recited limits of 1 to about 4.5, but also to include individual numerals such as 2, 3, 4, and sub-ranges such as 1 to 3, 2 to 4, etc. The same principle applies to ranges reciting only one numerical value, such as “less than about 4.5,” which should be interpreted to include all of the above-recited values and ranges. Further, such an interpretation should apply regardless of the breadth of the range or the characteristic being described.

Any steps recited in any method or process claims may be executed in any order and are not limited to the order presented in the claims. Means-plus-function or step-plus-function limitations will only be employed where for a specific claim limitation all of the following conditions are present in that limitation: a) “means for” or “step for” is expressly recited; and b) a corresponding function is expressly recited. The structure, material or acts that support the means-plus function are expressly recited in the description herein. Accordingly, the scope of the invention should be determined solely by the appended claims and their legal equivalents, rather than by the descriptions and examples given herein.

### EXAMPLE EMBODIMENTS

An initial overview of technology embodiments is provided below and then specific technology embodiments are described in further detail later. This initial summary is intended to aid readers in understanding the technology more quickly but is not intended to identify key features or essential features of the technology nor is it intended to limit the scope of the claimed subject matter.

RF signal amplifiers configured to amplify a signal over a frequency range that is greater than 1 octave can emit spurious harmonic signals due to non-linearities in the operation of the RF amplifiers. Additionally, other RF parameters, such as gain, power output, bandwidth, power efficiency, linearity, input and output impedance matching, and heat dissipation tend to degrade over wide bandwidths. Thus, there is an advantage to designing RF signal amplifiers that support less than an octave bandwidth.

Many types of communication systems, such as cellular base stations and user equipment (UEs) are specifically designed to transmit and receive signals at specific frequencies and bandwidths. These communication systems can include RF signal amplifiers and diplexers that are configured to operate within those specific frequencies and bandwidths. The RF signal amplifiers and diplexers typically include guard bands, which are bands in which the signal is not amplified. The use of guard bands allows separate RF amplifiers to be used that are configured to amplify specific signal bands.

It is often advantageous to amplify a wide RF spectrum rather than filtering and amplifying specific signal bands separately. Wideband amplification decreases complexity and cost. However, wideband amplification creates harmonics or intermodulation products that are then amplified by the wideband amplification system. RF over fiber optic systems used in distributed antenna systems (DAS) are sometimes configured for wideband amplification. Ultra-wideband (UWB) is an example of a wide bandwidth system that can use wide bandwidth amplification. RF receivers are also often wideband and would benefit from embodiments of the invention.

A wideband RF amplifier using cross-over diplexers is described herein. The wideband RF amplifier can be configured to amplify signals over wide bandwidths using cross-over diplexers to split a wideband input spectrum into multiple RF spectrum ranges distributed along multiple RF paths, with each RF spectrum including a fraction (sub-band) of the total bandwidth of the wideband input signal. These sub-bands can then be amplified using selected amplifiers that are configured for the specific sub-band and then re-combined using additional cross-over diplexers so that the combined signal covers the full bandwidth of the input signal, without guard bands.

Cross-over diplexers can be used that split wide-band RF input signals into contiguous sub-bands, which, together, cover the full input bandwidth of the wide-band RF input signal without guard bands. In addition, in selected embodiments, the cross-over diplexers can provide some useful filtering of harmonic products and differences to reduce the power of unwanted signals in the amplified output signal.

The sub-band components, such as the RF amplifiers, can be optimized for a reduced bandwidth of a specific sub-band, resulting in improved amplifier performance, including but not limited to intermodulation (i.e. secondary and tertiary intermodulation (IM2, IM3), amplifier gain, amplifier gain flatness & ripple, amplifier amplitude and phase response, amplifier power efficiency, an amplifier's 1 dB point (P1dB), and the amplifier's saturation point (Psat).

The sub-band signals can then be coherently combined by adding phase & amplitude equalization, allowing the combined full bandwidth signals to be fed with reduced harmonic spurious elements to an output, such as a single antenna, a DAS, or other RF equipment.

In an embodiment, the cross-over diplexers can be configured with sub-bands that are less than an octave bandwidth. By having less than one octave in bandwidth, the second harmonic distortion products are reduced by the stop band rejection of the diplexers.

Embodiments of the invention can be used to improve the performance of wide-band optical DAS and wide-band RF repeaters to amplify wide-band signals with reduced harmonic distortion.

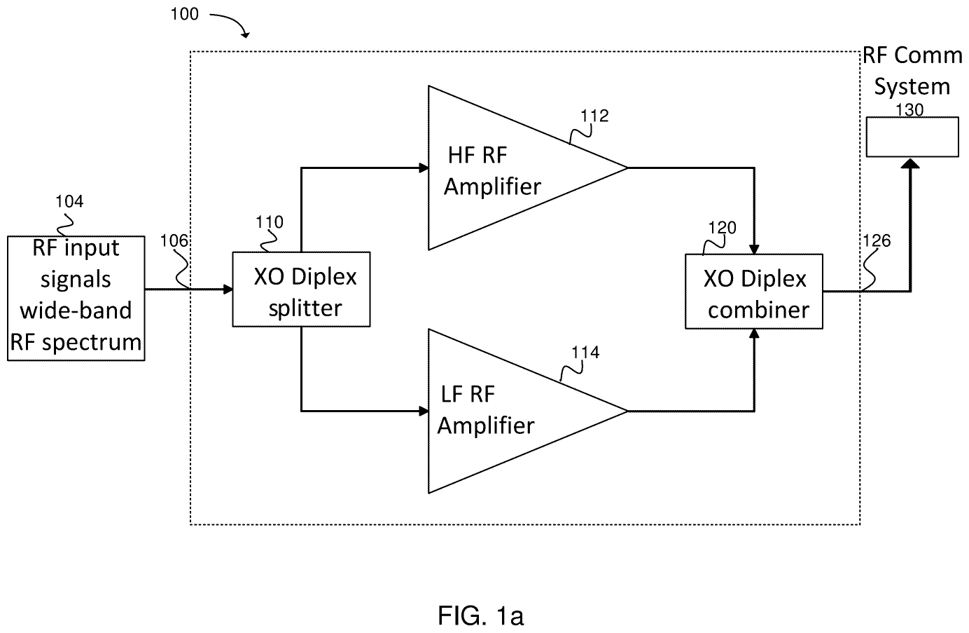

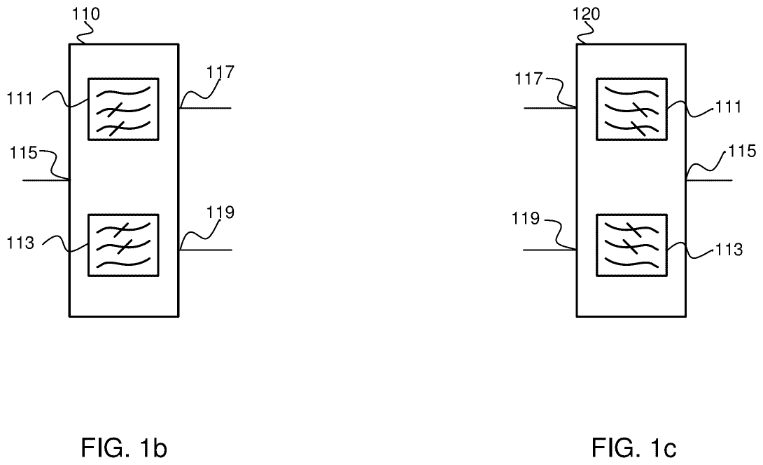

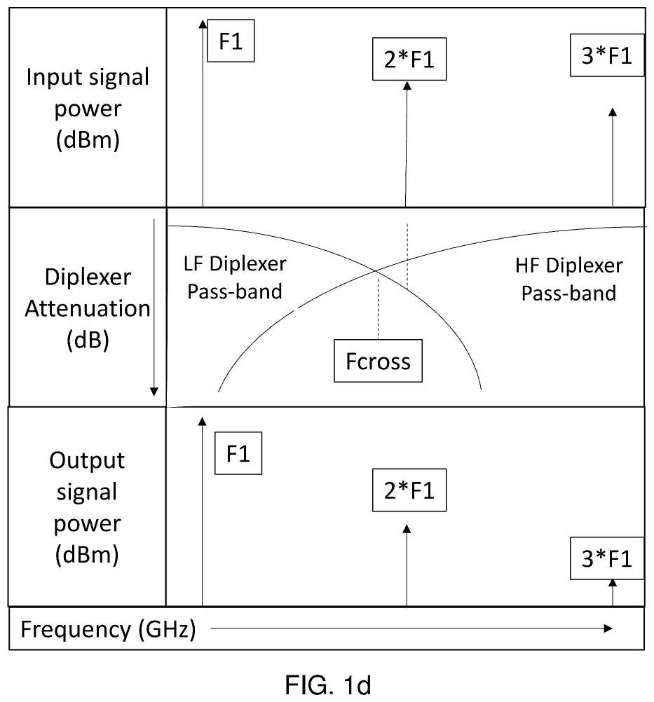

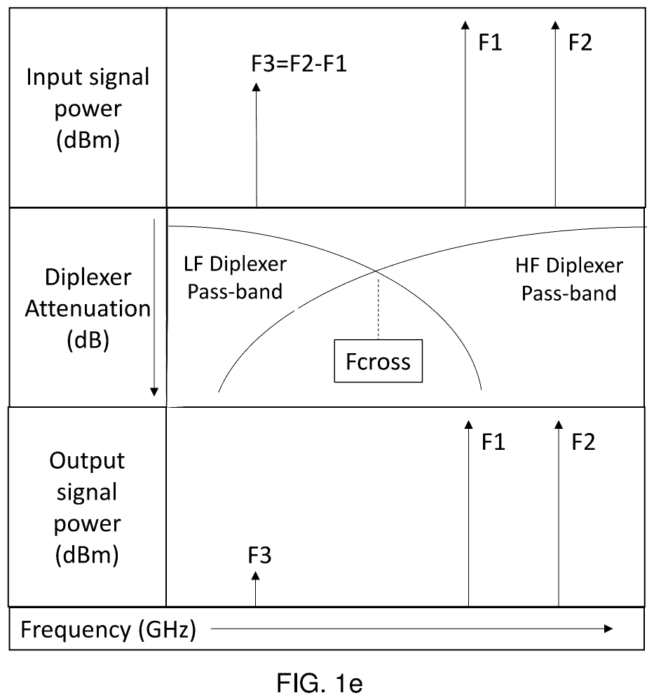

FIG. 1a illustrates an embodiment of a wide-band RF amplifier 100 using cross-over diplexers. The wide-band RF amplifier comprises a first port 106 configured to receive a wide-band RF spectrum that includes RF signals 104 within the wide-band RF spectrum. A cross-over (XO) diplexer splitter 110 is coupled to the first port 106. The cross-over diplexer splitter 110 is configured to filter the RF signals 104 in the RF wide-band spectrum into a low frequency (LF) pass-band with the RF signals including an LF signal within the LF pass-band and a high frequency (HF) pass-band with RF signals including an HF signal within the HF pass-band, with the LF pass-band crossing the HF pass-band at a cross-over frequency.

FIG. 1d illustrates an example of the LF pass-band and the HF pass-band. The actual frequency and power level at which the LF and HF pass-bands start and stop is dependent on the desired parameters of the RF communication system that is configured to use the wide-band RF amplifier 100.

In one example illustrated in FIG. 1b, the cross-over diplexer splitter 110 is comprised of a port 115 configured to receive the RF input signals in the wide-band RF spectrum and communicate it to a high pass filter 111 configured to pass the HF signal via an HF signal port 117, and a low pass filter 113 configured to pass the LF signal via an LF signal port 119. The high pass filter 111 and the low pass filter 113 are designed to have a same cross-over frequency, Fcross, as shown in FIG. 1d.

In one example, the high pass filter 117 and the low pass filter 119 in the diplexers 110, 120 can be designed as Butterworth filters having the same cross-over frequency. Alternatively, other filter designs may be used, including but not limited to Chebyshev, Bessel, and Elliptic filters.

Returning to FIG. 1a, an HF RF amplifier 112 is configured to amplify the HF signal communicated from the cross-over diplexer splitter 110 within an HF amplification pass-band of the HF RF amplifier to form an amplified HF signal. An LF RF amplifier 114 is configured to amplify the LF signal communicated from the cross-over diplexer splitter 110 within an LF amplification pass-band of the LF RF amplifier to form an amplified LF signal.

In one example, the HF amplification pass-band of the HF RF amplifier 112 can include at least a portion of the LF pass-band that is beyond the cross-over frequency Fcross. In addition, the LF amplification pass-band of the LF RF amplifier 114 can includes at least a portion of the HF pass-band that is beyond the cross-over frequency Fcross. The LF RF amplifier 114 is configured to amplify a majority of the power in the LF sub-band. The HF RF amplifier 112 is configured to amplify a majority of the power in the HF sub-band.

A cross-over (XO) diplexer combiner 120 is configured to combine the amplified HF signal and the amplified LF signal and output amplified RF signals in the wide-band RF spectrum at a second port 126. The cross-over diplexer combiner 120, illustrated in the example of FIG. 1c, is comprised of the high pass filter 111 and the low pass filter 113. The cross-over diplexer combiner 120 can receive the amplified LF signal at the LF signal port 119 and the amplified HF signal at the HF signal port 117 and route the amplified LF signal and the amplified HF signal through the high-pass filter 111 and the low-pass filter 113, respectively. The amplified HF signal and the amplified LF signal can be combined and output at the port 115 as a amplified RF signals in the wide-band RF spectrum. At Fcross (FIG. 1d), approximately half of the power is contained in the LF signal and approximately half of the power is contained in the HF signal.

The amplified RF signals in the wide-band RF spectrum can be communicatively coupled to an RF communication system 130, as shown in FIG. 1a. Examples of an RF communication system 130 include, but are not limited to, an RF wide-band repeater, a distributed antenna system (DAS), an optical DAS, or one or more antennas. These embodiments will be described further in the proceeding paragraphs.

In one example, the cross-over diplexer splitter 110 and cross-over diplexer combiner 120 can be substantially the same, with the same high pass filter 111 and low pass filter 113 designs, and the same Fcross (FIG. 1d). In measurements of physical systems, there can be relatively small differences between the cross-over diplexer splitter 110 and the cross-over diplexer combiner 120 due the slight variations in manufacturing of the filters 111, 113 and components in the cross-over diplexers 110, 120.

As previously discussed, the cross-over diplexers 110, 120 can be configured with sub-bands (i.e. the LF pass-band and the HF pass-band) that are less than an octave in bandwidth. The LF signal and HF signal are amplified by the HF RF amplifier 112 and the LF RF amplifier 114, respectively, using non-linear processes. The non-linear processes result in additional signals output from the amplifiers, including harmonics (second and third), intermodulation distortion, and difference signals.

FIG. 1d illustrates an example in which the LF signal and the HF signal are designated by F1 and F2. By having less than one octave in bandwidth in F1 and F2, the harmonic distortion products (2*F1, 3*F1) that are illustrated in FIG. 1d are greater in frequency than the Fcross of the low-pass filter 113 and high-pass filter 111. Accordingly, the low-pass filter 113 in the cross-over diplexer combiner 120 passes the F1 signal, while reducing the amplitude of the harmonic distortion products 2*F1 and 3*F1, as shown in FIG. 1d, as measured at the second port 126 in FIG. 1a.

In one embodiment, a harmonic of the amplified LF signal is attenuated since the harmonic has a frequency that is greater than the cross-over frequency to enable the cross-over diplexer combiner to filter the harmonic with one of a low pass filter and a band pass filter.

Similarly, FIG. 1e illustrates how the difference signal F3=F2−F1, which is output by the HF RF amplifier 112 and the LF RF amplifier 114, is filtered by the HF high-pass filter 111 in the cross-over diplexer combiner 120 to reduce the amplitude of the difference signal F3 at the second port 126 in FIG. 1a, while passing the F2 signal.

In one embodiment, a difference signal of the amplified HF signal and the amplified LF signal has a frequency that is less than the cross-over frequency to enable the cross-over diplexer combiner to filter the harmonic with one of a high pass filter and a band pass filter.

In one embodiment, the second port 126 can be configured to be coupled to and communicate the RF signals 104 in the amplified RF wide-band spectrum to one or more of a radio frequency repeater, a distributed antenna system, or one or more antennas.

In an example, the second port 126 is configured to be coupled to one or more of a wide-band optical distributed antenna system or a bidirectional amplifier that is configured to be communicatively coupled to an output of the cross-over diplexer combiner 129 and receive the amplified RF signals in the wide-band RF spectrum with reduced second harmonic distortion to enable the RF signals within the RF wide-band spectrum to be amplified by or used by the wide-band optical distributed antenna system or the bidirectional amplifier with reduced harmonic distortion.

In one example, the wide-band RF amplifier 100 can be configured as a power amplifier for amplification of the RF signals in the wide-band RF input spectrum for transmission at an antenna.

In another example, the wide-band RF amplifier 100 is configured as a low noise amplifier (LNA) to amplify the RF signals in the wide-band RF spectrum.

The wide-band RF amplifier 100 can be configured as a power amplifier, LNA, or other type of desired RF amplifier based on the type of amplifiers 112, 114 used in the wide-band RF amplifier. For example, the amplifiers 112, 114 can be low noise amplifiers for the wide-band RF amplifier 100 to be configured as an LNA. The power amplifiers 112, 114 can be power amplifiers for the wide-band RF amplifier 100 to be configured as a power amplifier, and so forth.

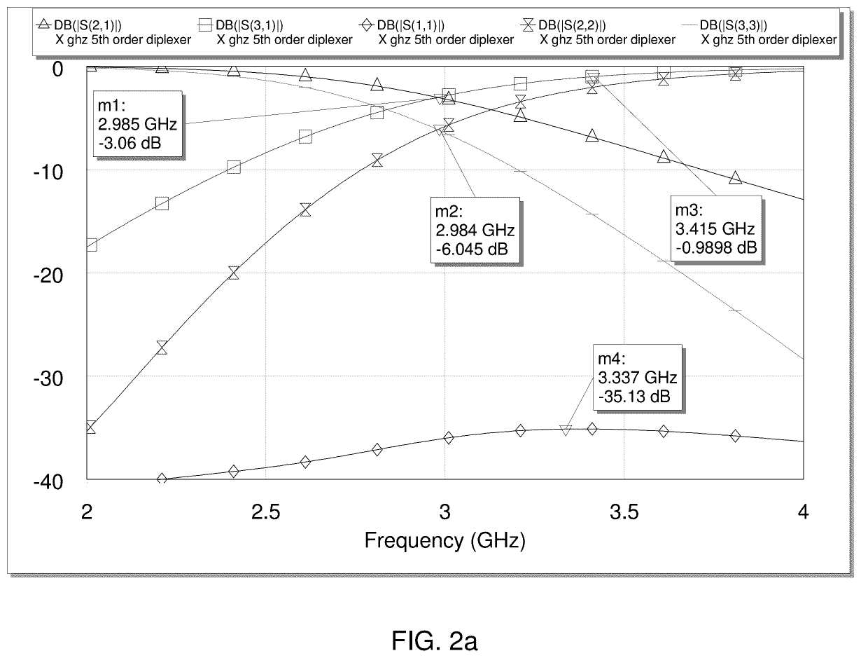

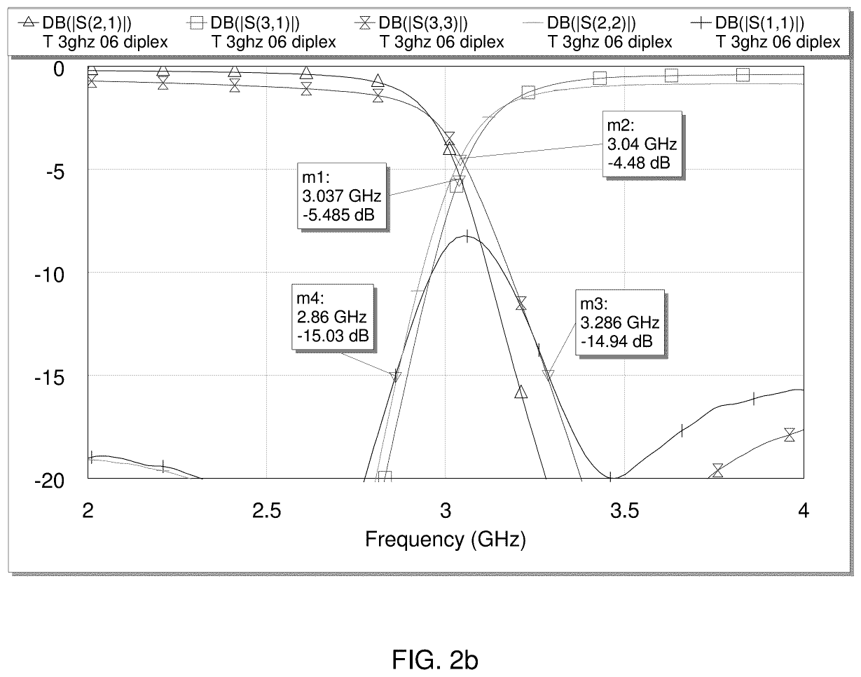

FIG. 2a illustrates an example of network analyzer measurements taken at the second port 126. In this example the cross-over frequency (Fcross) was designed to be 3 GHz. At Fcross, the insertion losses (s21 and s31) are approximately 3 dB, illustrating that approximately half the power at Fcross is provided from each of the HF & LF amplifiers 112, 114. Input return loss (s11) is greater than 30 dB and the output return losses (s22 & s33) are approximately 6 dB.

In contrast, FIG. 2b illustrates an example of network analyzer measurements when using typical diplexers designed with a band gap, instead of cross-over diplexers. In this example, The LF & HF pass-bands have been defined as frequencies where the return losses are greater than 15 dB. The space between the LF & HF pass-bands is defined as a guard band where the diplexer return losses are significantly degraded. In this example the guard band extends from 2.86 to 3.2 GHz, resulting in a guard band that is 340 MHz wide.

Signals that occupy this guard band will be negatively impacted by amplitude and phase distortion. This can be a significant disadvantage preventing a system from supporting signals in the guard band.

At the cross-over frequency in the example of FIG. 2b, the input return loss (s11) has degraded to 8 dB and the output return losses (s22 & s33) have degraded to 4.5 dB and the insertion losses (s21 & s31) to 5.5 dB. Using the diplexers with a bandgap, as illustrated in FIG. 2b, would result in significant distortion of the amplitude and phase of the amplified RF signals in the wide-band RF spectrum output at the second port 126 in FIG. 1a. The distortion can make it difficult or impossible to recover information carried on the amplified RF signals in the wide-band RF signal within the bandgap frequency range.

In one embodiment, the cross-over diplexer splitter is configured to filter the wide-band RF spectrum such that the LF signal and the RF signal each have a loss of approximately 3 decibels (dB) at the cross-over frequency relative to a signal power of the LF signal and the HF signal in the wide-band RF spectrum at an input of the cross-over diplexer splitter.

The use of different high pass and low pass filters 111, 113 in the cross-over diplexer splitter 110 can result in phase and amplitude differences between the amplified HF signal and the amplified LF signal output by the HF RF amplifier 112 and LF RF amplifier 114, respectively. In most cases, when using cross-over diplexers, phase and amplitude equalization to the sub-band paths can be useful to enable coherent re-combining of the sub-bands in the cross-over diplexer combiner 120. The phase and amplitude equalization can take into account multiple components within the wide-band RF amplifier 100, including but not limited to the high pass and low pass filters 111, 113 in the cross-over diplexer splitter 110, the HF RF amplifier 112, the LF RF amplifier 114, and the high pass and low pass filters 111, 113 in the cross-over diplexer combiner 120, to enable the amplified HF signal and the amplified LF signal output by the HF RF amplifier 112 and LF RF amplifier 114 to be combined with the LF signal and the HF signal having substantially similar phase and amplitude at the cross-over frequency (Fcross) in the cross-over diplexer combiner 120, thereby enabling the amplified RF signals in the wide-band RF spectrum to be communicated at the second port 126.

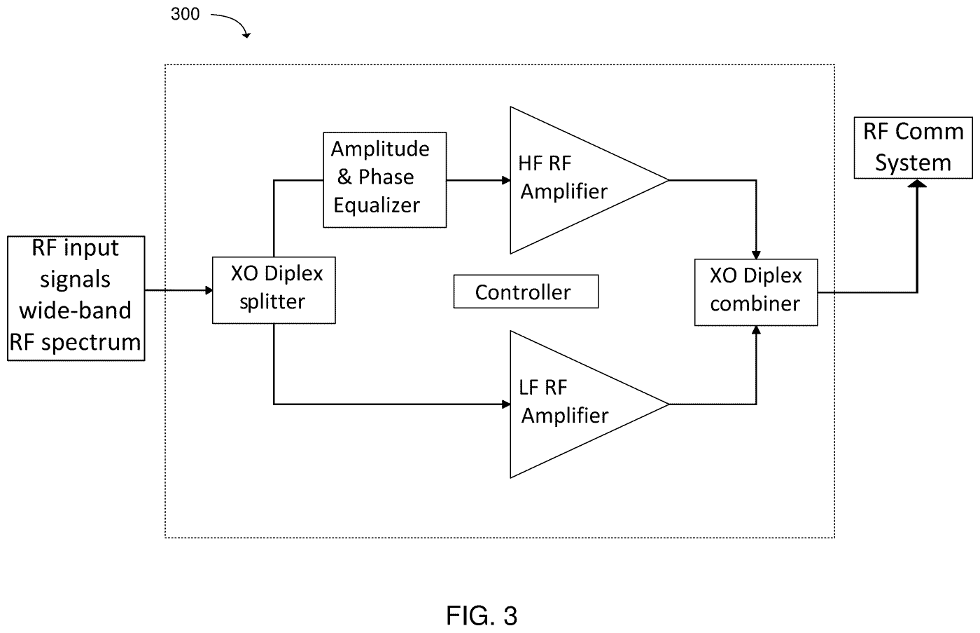

FIG. 3 illustrates an example embodiment in which a wide-band RF amplifier 300 with cross-over diplexers includes an amplitude and phase equalizer that is located prior to the HF RF amplifier. In this example, the amplitude and/or the phase of the HF signal communicated from the cross-over diplexer splitter can be adjusted prior to entering the HF RF amplifier. The amplitude and/or the phase of the HF signal can be adjusted such that the amplitude and phase of the amplified HF signal and the phase and amplitude of the LF signal are substantially similar at the cross-over diplexer combiner. The frequency at which the phase and amplitude of the HF signal and the LF signal are matched can be selected based on desired system specifications. In one example, the phase and amplitude of the HF signal and the LF signal can be matched at the cross-over frequency Fcross (FIG. 1d).

In one embodiment, the cross-over frequency Fcross of the amplified HF signal and the amplified LF signal in the cross-over diplexer combiner can be used to substantially match the phase and amplitude of the signals. The accuracy of the phase and amplitude match can be selected based on the desired system specifications for the RF communication system. In one example, the amplitude can be matched within 0.1 dB, 1 dB, 3 dB, or 4 dB. The phase can be matched within 0.1 degrees, 1 degree, or 5 degrees, depending on the desired accuracy for the RF communication system.

The amplitude and phase equalizer can be selected from various RF components used to alter the amplitude or phase of the HF signal. For example, the amplitude equalizer can be one or more of a fixed amplifier, a variable amplifier, an RF filter, a fixed attenuator, or a variable attenuator. The phase equalizer can be implemented using a delay line, a filter, or a phase shifter. In one example, the amplitude and phase of the HF signal can be equalized in the manufacturing and/or testing process by adjusting the amplitude and/or phase of the HF signal, in this example, by a predetermined amount to enable the HF signal to have a substantially similar amplitude and phase as the LF signal at a selected frequency within the HF frequency band or the LF frequency band, such as at the cross-over frequency Fcross. A repairment or lab technician can also adjust the amplitude of phase. Alternatively, the amplitude and phase equalizer can be actively updated using variable phase shifters, variable amplifiers, and/or variable attenuators. The variable components can be controlled by a controller. In one example, the controller can monitor the output of the cross-over diplexer combiner and adjust the phase and/or amplitude of the HF signal using the variable components to achieve a desired output at the second port 126 (FIG. 1a).

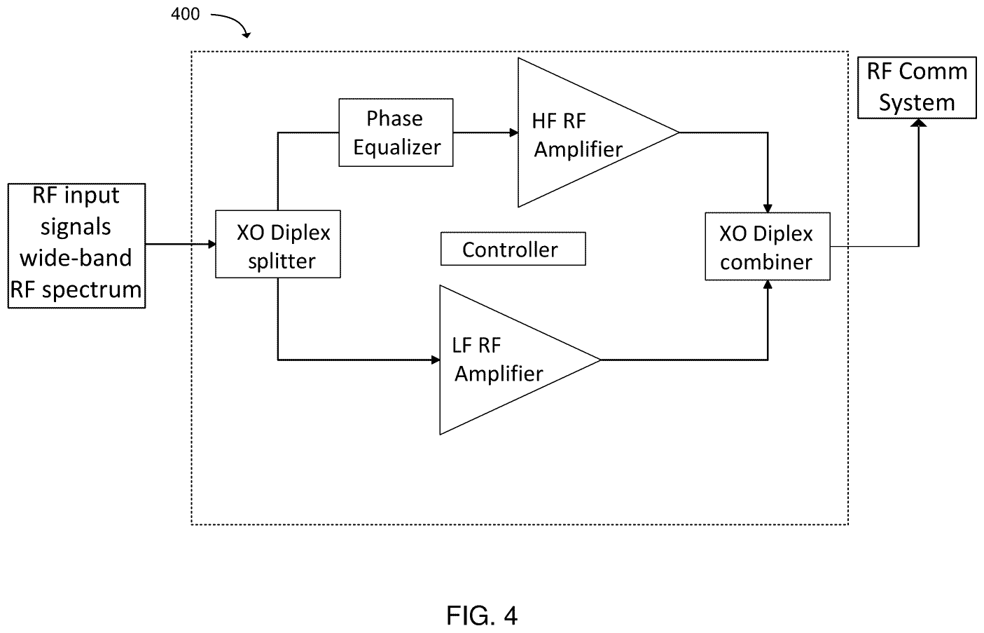

FIG. 4 illustrates another example of an embodiment in which a wide-band RF amplifier 400 with cross-over diplexers includes a phase equalizer to change the phase of the HF signal prior to the HF RF amplifier to enable the phase of the HF signal and the phase of the LF signal to be matched. The phase equalizer can be implemented using a delay line, a filter, or a phase shifter.

The phase of the HF signal can be changed and matched so that the amplified HF LF signal and the amplified HF signal are matched as described with respect to FIG. 3. In this example, if it is necessary to equalize the amplitude of the HF signal with the amplitude of the LF signal prior to the HF RF amplifier. The amplitude can be altered using one or more of the HF RF amplifier or the LF RF amplifier such that the amplitude and phase of the amplified HF signal and the phase and amplitude of the amplified LF signal are substantially similar at the cross-over diplexer combiner at a selected frequency, such as Fcross.

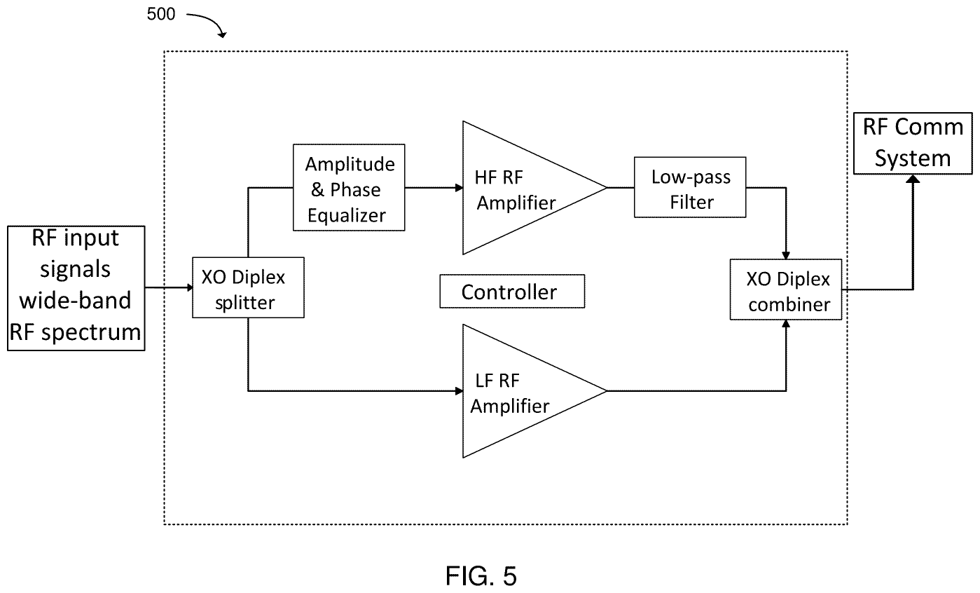

FIG. 5 illustrates another example of an embodiment in which a wide-band RF amplifier 500 with cross-over diplexers includes an additional low-pass filter at the output of the HF RF amplifier, in addition to the amplitude and phase equalizer located prior to the HF RF amplifier, as illustrated in FIG. 5. The amplitude and phase equalizer can operate as previously described with respect to FIG. 3. In the example of FIG. 5, the additional low-pass filter can be designed to change the phase and amplitude of the amplified HF signal such that the amplitude and phase of the amplified HF signal and the phase and amplitude of the amplified LF signal are substantially similar at the cross-over diplexer combiner at a selected frequency, such as Fcross. In addition, the additional low-pass filter at the output of the HF RF amplifier can be used to further attenuate unwanted harmonics and intermodulation, including but not limited to the second & third harmonic components at 2*F1 & 3*F1 caused by non-linear amplification of the HF signal and the LF signal.

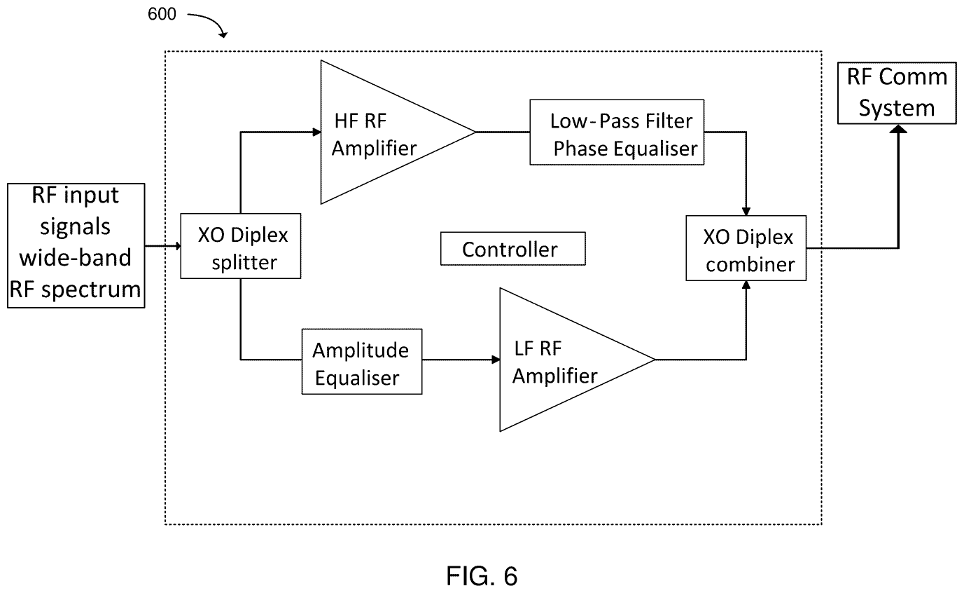

FIG. 6 illustrates another example of an embodiment in which a wide-band RF amplifier 600 with cross-over diplexers includes a low-pass filter and a phase equalizer at the output of the HF RF amplifier, and an amplitude equalizer at the input of the LF RF amplifier. In this example, the phase equalizer at the output of the HF RF amplifier can be implemented using a delay line, a filter, or a phase shifter, as previously described with respect to FIG. 3. Similarly, the amplitude equalizer at the input of the LR RF amplifier can be implemented to adjust the amplitude of the LF signal using one or more of a fixed amplifier, a variable amplifier, an RF filter, a fixed attenuator, or a variable attenuator, as previously described with respect to FIG. 3. The low-pass filter at the output of the HF RF amplifier can be designed to change the phase and amplitude of the amplified HF signal such that the phase and amplitude of the amplified HF signal and the phase and amplitude of the amplified LF signal are substantially similar at the cross-over diplexer combiner at a selected frequency, such as Fcross. In this example, the low-pass filter and phase equalizer at the output of the HF RF amplifier and the amplitude equalizer located prior to the LF RF amplifier can be used together to alter the amplitude and phase of the HF signal and the LF signal such that the amplitude and phase of the amplified HF signal and the amplitude and phase of the amplified LF signal are substantially similar at the cross-over diplexer combiner at a selected frequency, such as Fcross. As in FIG. 3, the phase and amplitude equalizer(s) in the examples of FIGS. 4, 5 and 6 can be passive and/or actively controlled using a controller.

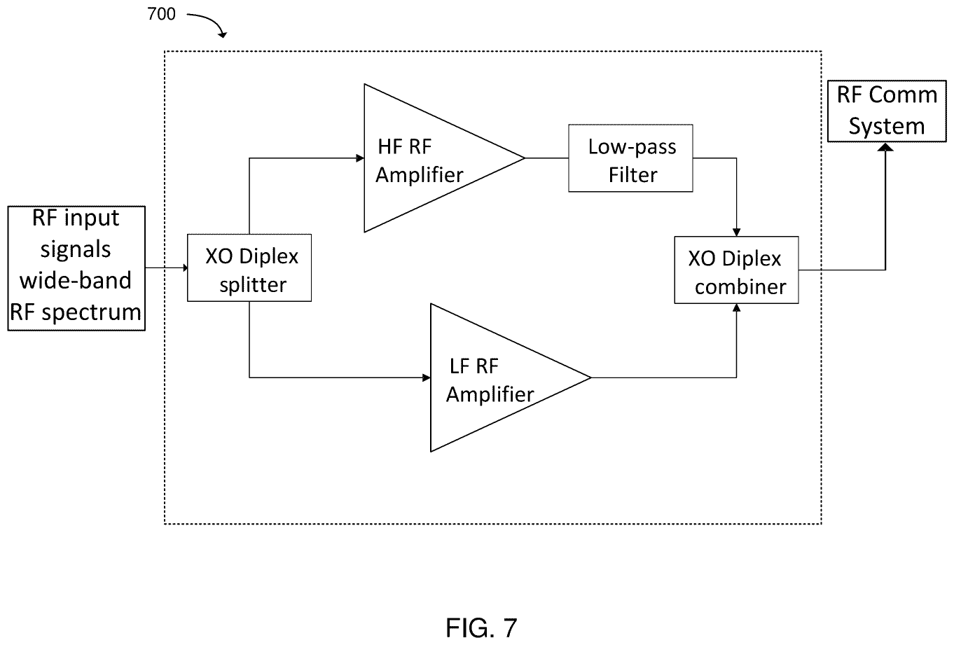

FIG. 7 illustrates another example of an embodiment in which a wide-band RF amplifier 700 with cross-over diplexers includes a low-pass filter at the output of the HF RF amplifier. As in the example of FIG. 5, the additional low-pass filter can be designed to change the phase and amplitude of the amplified HF signal such that the amplitude and phase of the amplified HF signal and the amplitude and phase of the amplified LF signal are substantially similar at the cross-over diplexer combiner at a selected frequency, such as Fcross. In addition, the additional low-pass filter at the output of the HF RF amplifier can be used to further attenuate unwanted harmonics, such as intermodulation and second & third harmonic components at 2*F1 & 3*F1 caused by non-linear amplification. In contrast with the example illustrated in FIG. 5, the example illustrated in FIG. 7 does not include any additional components for phase equalization. Accordingly, the additional low-pass filter at the output of the HF RF amplifier is the only element used to match the phases of the amplified HF signal and the amplified LF signal. This can be helpful in low cost and low power systems.

In one embodiment, the wide-band RF amplifier 104 (FIG. 1a), can further comprise an amplitude equalizer located between the cross-over diplexer splitter and the cross-over diplexer combiner to substantially equalize an amplitude of the LF signal and an amplitude of the HF signal at the cross-over frequency at an input to the cross-over diplexer combiner; and a phase equalizer located between the cross-over diplexer splitter and the cross-over diplexer combiner to substantially equalize a phase of the amplified LF signal and a phase of the amplified HF signal at the cross-over frequency at the input to the cross-over diplexer combiner.

The amplitude equalizer can be one or more of a fixed amplifier, a variable amplifier, a filter, a fixed attenuator, or a variable attenuator.

The phase equalizer can be one or more of a delay line, a phase shifter, or a filter.

The cross-over diplexer splitter and the cross-over diplexer combiner are configured to split the wide-band RF spectrum into contiguous sub-bands to amplify the HF signal and the LF signal within a selected bandwidth of the wide-band RF spectrum without guard bands. Accordingly, the HF pass-band and the LF pass-band are contiguous with no guard band between the HF pass-band and the LF pass-band.

In an embodiment, the HF signal and the LF signal can be amplitude and phase balanced at the cross-over frequency.

The wide-band RF amplifier 104 can be configured to amplify the HF signal and the LF signal without an attenuation guard band at the cross-over frequency.

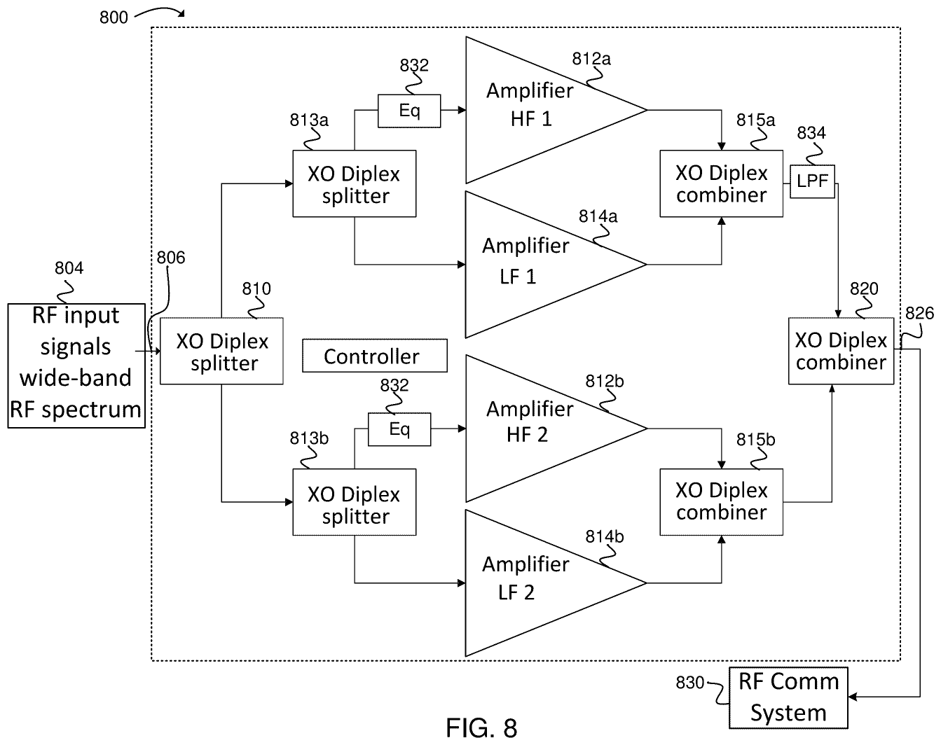

FIG. 8 illustrates another example of an embodiment of a wide-band RF amplifier 800 with cross-over diplexers. In the previous embodiments, the RF signals in the wide-band RF spectrum has been split into two components, a high frequency (HF) signal with an HF band and a low frequency (LF) signal with an LF band. The example of FIG. 8 illustrates that a signal can be divided into 2n signals, where n is a positive integer, with each signal having a contiguous band. The 2n signals are then amplified, and then recombined as previously described to form a wide-band amplified signal.

In the example of FIG. 8, the RF input signal 804 in the wide-band RF spectrum is communicated to a first port 806 and divided into 2n separate signals using 2n+1 cross-over diplexer splitters, 2ⁿ amplifiers, and 2n+1 cross-over diplexer combiners to output amplified RF signals in the wide-band RF spectrum at a second port 826 to an RF communication system 830. In the specific example of FIG. 8, the integer n is set to 2, so there are 4 separate signals (2 HF signals and 2 LF signals), with 3 cross-over diplexer splitters, 4 amplifiers, and 3 cross-over diplexer combiners.

More generally, the wide-band RF amplifier 800 with cross-over diplexers illustrated in the example of FIG. 8 is comprised of a first port 806 configured to receive RF signals 804 in a wide-band RF spectrum. A first cross-over diplexer splitter 810 is communicatively coupled to the first port 806 to receive the RF signals 804 in the wide-band RF spectrum. 2n cross-over diplexer splitters 813a, 813b are communicatively coupled to an output of the first cross-over diplexer splitter 810, where n is a positive integer. Each of the 2n cross-over diplexer splitters 813a, 813b are configured to receive a portion of the RF signal 804 in the wide-band RF spectrum and filter a portion of the RF signal 804 into a low frequency (LF) signal having an LF pass-band and a high frequency (HF) signal having an HF pass-band. As shown in FIG. 1c, the LF pass-band is configured to cross the HF pass-band at a cross-over frequency, Fcross using specifically designed high pass and low pass filters 111, 113 (FIGS. 1b, 1c). An HF RF amplifier 812a, 812b is coupled to an output of one or more of the 2n cross-over diplexer splitters 813a, 813b. The HF RF amplifiers 812a, 812b are configured to amplify the HF signal within an HF amplification pass-band to form an amplified HF signal. An LF RF amplifier 814a, 814b is coupled to an output of the one or more of the 2n cross-over diplexer splitters 813a, 813b and configured to amplify the LF signal within an LF amplification pass-band to form an amplified LF signal. The HF amplification pass-band includes at least a portion of the LF pass-band that is beyond the cross-over frequency, Fcross. The LF amplification pass-band includes at least a portion of the HF pass-band that is beyond the cross-over frequency, Fcross. The high pass and low pass filters illustrated in FIGS. 1b and 1c are not intended to be limiting. Bandpass filters may also be used to filter the RF signals in the wide-band RF spectrum.

The wide-band RF amplifier 800 further comprises 2n cross-over diplexer combiners 815a, 815b. One or more of the cross-over diplexer combiners 815a, 815b is coupled to an output of the HF RF amplifiers 812a, 812b and the LF RF amplifiers 814a, 814b of the one or more of the 2n cross-over diplexer splitters 813a, 813b, respectively. A final cross-over diplexer combiner 820 is configured to combine the amplified HF signals from the HF RF amplifiers 812a, 812b that are coupled to the outputs of the one or more of the 2n cross-over diplexer splitters 813a, 813b and the amplified LF signals from the LF RF amplifiers 814a, 814b that are coupled to the outputs of the one or more of the 2n cross-over diplexer splitters 813a, 813b and output amplified RF signals in the wide-band RF spectrum at a second port 826.

Amplitude and phase equalizers 832 and additional low pass filters 834, as previously discussed with respect to FIGS. 3 through 7, can be added between the first port 806 and the second port 826 to equalize the amplitude and phase of the 2n separate signals (i.e. the HF signals and the LF signals) to enable them to be combined coherently in phase and with a substantially similar amplitude at the 2n+1 cross-over diplexer combiners, 815a, 815b and 820 in this specific example. The location of the amplitude and phase equalizers 832 and additional LPF 834 illustrated in the example of FIG. 8 is not intended to be limiting. Any of the examples of FIGS. 3 to 7 can be applied to the more general example in FIG. 8 to provide phase and amplitude adjustment of the n HF signals and the n LF signals to enable them to be recombined at the final cross-over diplexer combiner 820.

In one embodiment, the first cross-over diplexer splitter 810 in the wide-band RF amplifier 800 is configured to filter the RF signals 804 in the wide-band RF spectrum such that the LF signal and the HF signal each have a loss of approximately 3 decibels (dB) at the cross-over frequency (Fcross) relative to a signal power of the LF signal and the HF signal in the wide-band RF spectrum at an input of the cross-over diplexer splitter 810

In one embodiment, the wide-band RF amplifier 800 further comprises one or more of an amplitude equalizer 832 located between the first cross-over diplexer splitter 810 and the final cross-over diplexer combiner 820 to substantially equalize an amplitude of the amplified LF signal and an amplitude of the amplified HF signal at the cross-over frequency (Fcross) at an input to the final cross-over diplexer combiner 820; and a phase equalizer 832 located between the first cross-over diplexer splitter 810 and the final cross-over diplexer combiner 820 to substantially equalize a phase of the amplified LF signal and a phase of the amplified HF signal at the cross-over frequency (Fcross) at the input to the final cross-over diplexer combiner 820.

In one embodiment, the amplitude equalizer 832 of the wide-band RF amplifier 800 can be one or more of a fixed amplifier, a variable amplifier, a filter, a fixed attenuator, or a variable attenuator. The phase equalizer 832 can be one or more of a delay line, a phase shifter, or a filter.

In one embodiment, a bandwidth of the wide-band RF spectrum received at the input port 806 of the wide-band RF amplifier 800 is greater than one octave.

In one embodiment, a bandwidth of each of the LF pass-bands with the amplified LF signals in the wide-band RF amplifier 800 is less than an octave to enable a harmonic of each of the amplified LF signals to be attenuated by one of a low pass filter or a band pass filter in the cross-over diplexer combiner since the harmonic has a frequency that is greater than the cross-over frequency to enable the cross-over diplexer combiner to filter the harmonic with one of the low pass filter and the band pass filter.

In one embodiment, a difference signal of the amplified HF signal and the amplified LF signal in the wide-band RF amplifier 800 has a frequency that is less than the cross-over frequency to enable the cross-over diplexer combiner to filter the harmonic with one of a high pass filter and a band pass filter.

In one embodiment, the cross-over diplexer splitters 813a, 813b are configured to split the RF signals 804 in the wide-band RF spectrum into contiguous sub-bands to enable the cross-over diplexer combiners 815a, 815b to combine the amplified LF signals within the LF pass-band with the amplified HF signals within the HF pass-band to form the amplified RF signals in the wide-band RF spectrum without guard bands between the passband of the amplified LF signals and the passband of the amplified HF signals.

In one embodiment, the amplified HF signals and the amplified LF signals are one or more of amplitude balanced and phase balanced at the cross-over frequency in the wide-band RF amplifier 800.

In one embodiment, the HF signals and the LF signals in the wide-band RF amplifier 800 are amplified without an attenuation guard band at the cross-over frequency.

In one embodiment, the HF pass-band and the LF pass-band are contiguous with no guard band between the HF signals and the LF signals output from each of the 2n cross-over diplexer splitters in the wide-band RF amplifier 800.

In one embodiment, the second port 826 of the wide-band RF amplifier 800 is configured to be coupled to and communicate the amplified RF signals in the wide-band RF spectrum to one or more of a radio frequency repeater, a distributed antenna system, or one or more antennas.

In one embodiment, the wide-band RF amplifier 800 is configured as a power amplifier for amplification of the RF signals in the wide-band RF spectrum for transmission at an antenna.

In one embodiment, the wide-band RF amplifier 800 is configured as a low noise amplifier (LNA) to amplify the RF signals in the wide-band RF spectrum.

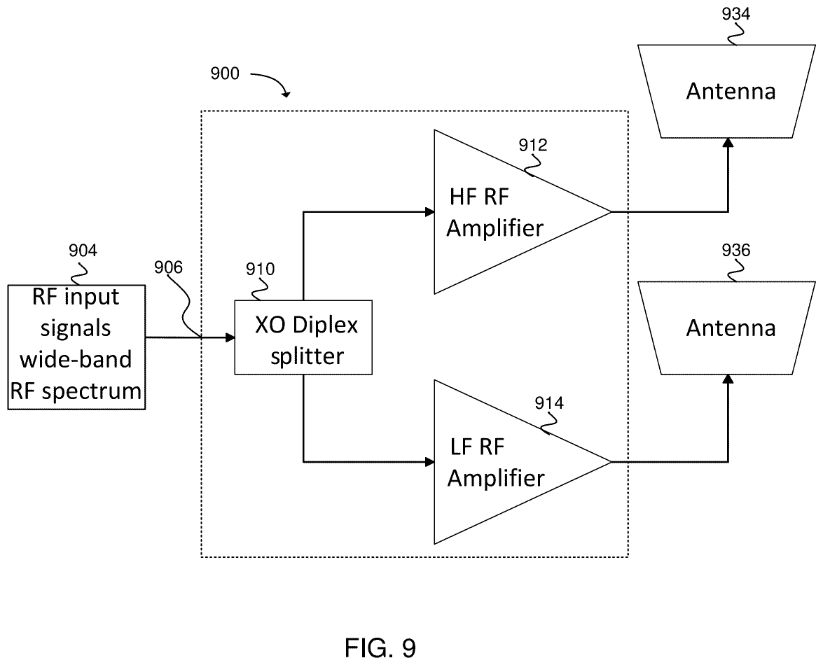

FIG. 9 illustrates another example of an embodiment of a wide-band RF amplifier 900 with a cross-over diplexer. In this example, RF input signals 904 in the wide-band RF spectrum are communicated to a first port 906 and divided into two portions by the cross-over diplexer splitter 910, comprising an HF signal that is directed to an HF RF amplifier 912 and an LF signal that is directed to an LF RF amplifier 914. An HF RF band of the HF signal and an LF RF band of the LF signal can be contiguous. The HF RF amplifier 912 and the LF RF amplifier 914 can be configured to amplify a signal with a bandwidth less than one octave. The HF RF amplifier 912 can output an HF RF amplified signal that can be directed to an RF communication system. Similarly, the LF RF amplifier 914 can output an LF RF amplified signal that can be directed to the same, or a separate RF communication system. In the example illustrated in FIG. 9, the RF communication system can be a first antenna 934 coupled to an output of the HF RF amplifier 912, and a second antenna 936 coupled to an output of the LF RF amplifier 914. The first antenna 934 and the second antenna 936 can be configured to transmit the HF RF amplified signal and the LF RF amplified signal in the contiguous HF band and LF band, respectively. An advantage of directing the output of the contiguous band signals to separate RF communication systems is that it is not necessary to implement amplitude and phase equalizers on the LF and HF amplified signals since the amplified signals are not being combined. In contrast with the examples in FIGS. 3 to 8, the output of the HF RF amplifier 912 and the output of the LF RF amplifier 914 can be communicated to separate RF communication systems, such as the antennas 934, 936, or a different communication system such as separate repeaters or DAS without the use of amplitude and phase equalizers. However, filtering of the HF signal and the LF signal output by the HF RF amplifier 912 and the LF RF amplifier 914, respectively, may still be used to attenuate signals outside of the desired pass-bands of the HF signal and the LF signal.

In accordance with one embodiment, a wide-band radio frequency (RF) amplifier 900 using cross-over diplexers is disclosed. The wide-band RF amplifier 900 can comprise a first port 906 configured to receive a wide-band RF spectrum that includes RF signals 904 within the wide-band RF spectrum. A cross-over diplexer splitter 910 can be coupled to the first port 906. The cross-over diplexer splitter 910 is configured to filter the RF signals in the wide-band RF spectrum into a low frequency (LF) pass-band with the RF signals including an LF signals within the LF pass-band and a high frequency (HF) pass-band with the RF signals including an HF signal within the HF pass-band, with the LF pass-band crossing the HF pass-band at a cross-over frequency. The wide-band RF amplifier 900 can further comprise an HF RF amplifier 912 configured to amplify the HF signal within an HF amplification pass-band to form an amplified HF signal. An LF RF amplifier 914 is configured to amplify the LF signal within an LF amplification pass-band to form an amplified LF signal. The HF amplification pass-band can include at least a portion of the LF pass-band that is beyond the cross-over frequency; and the LF amplification pass-band can include at least a portion of the HF pass-band that is beyond the cross-over frequency. The HF RF amplifier 912 is configured to be communicatively coupled to a first antenna 934 to transmit the HF amplified signal; and the LF amplifier 914 is configured to be communicatively coupled to a second antenna to transmit the LF signal 936. In one embodiment, the cross-over diplexer splitter 910 can be configured to split the wide-band RF input signal 904 into contiguous sub-bands.

In one embodiment, the cross-over diplexer splitter 910 is configured to split the wide-band RF input spectrum into contiguous sub-bands.

In one embodiment, the cross-over diplexer splitter 910 is configured to filter the wide-band RF spectrum such that the LF signal and the HF signal each have a loss of approximately 3 decibels (dB) at the cross-over frequency relative to a signal power of the LF signal and the HF signal at an input of the cross-over diplexer splitter 910.

In one embodiment, a bandwidth of the wide-band RF spectrum at the wide-band RF amplifier 900 is greater than one octave.

In one embodiment, a bandwidth of the HF pass-band is less than one octave and a bandwidth of the LF pass-band is less than one octave at the wide-band RF amplifier 900.

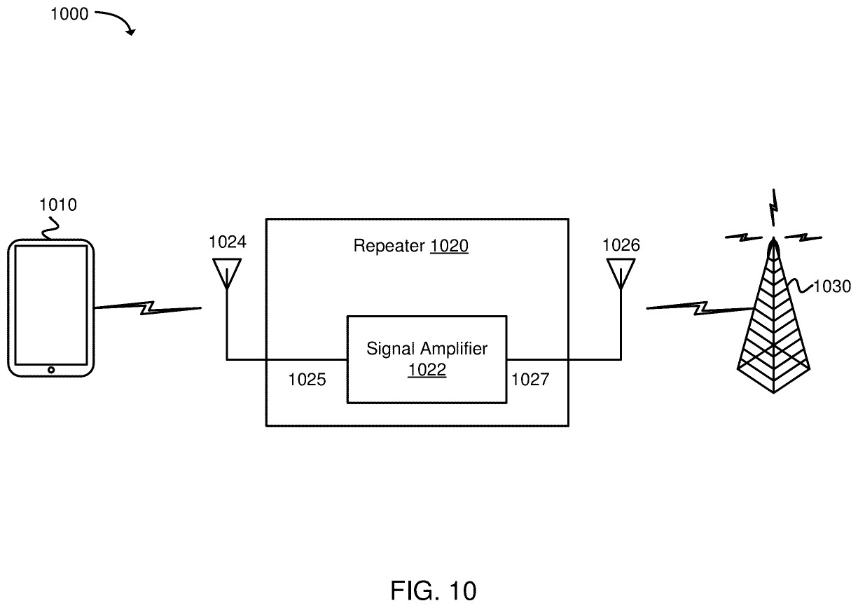

In one embodiment, a wide-band RF amplifier with cross-over diplexers, such as one or more of the wide-band RF amplifiers 300, 400, 500, 600, 700, 800 or 900 illustrated in the examples of FIGS. 3-9, can be used to amplify a wide-band signal in a wide-band RF repeater. FIG. 10 provides an example illustration of an exemplary repeater 1020 in communication with a wireless device 1010 and a base station 1030. The repeater 1020 can be referred to as a signal booster. A repeater can be an electronic device used to amplify (or boost) signals. The repeater 1020 (also referred to as a cellular signal amplifier) can improve the quality of wireless communication by amplifying, filtering, and/or applying other processing techniques via a signal amplifier 1022 to uplink signals communicated from the wireless device 1010 to the base station 1030 and/or downlink signals communicated from the base station 1030 to the wireless device 1010. In other words, the repeater 1020 can amplify or boost uplink signals and/or downlink signals bi-directionally. The repeater can be referred to as a bidirectional amplifier. In one example, the repeater 1020 can be at a fixed location, such as in a home or office. Alternatively, the repeater 1020 can be attached to a mobile object, such as a vehicle or a wireless device 1010.

In one configuration, the repeater 1020 can include a server antenna 1024 (e.g., an inside antenna, device antenna, or a coupling antenna) and a donor antenna 1026 (e.g., a node antenna or an outside antenna). The donor antenna 1026 can receive the downlink signal from the base station 1030. The downlink signal can be provided to the signal amplifier 1022 via an RF communication path, such as a second coaxial cable 1027 or other type of radio frequency connection operable to communicate radio frequency signals. The signal amplifier 1022 can include one or more cellular signal amplifiers for amplification and filtering. The downlink signal that has been amplified and filtered can be provided to the server antenna 1024 via a first coaxial cable 1025 or other type of radio frequency connection operable to communicate radio frequency signals. The server antenna 1024 can wirelessly communicate the downlink signal that has been amplified and filtered to the wireless device 1010.

Similarly, the server antenna 1024 can receive an uplink signal from the wireless device 1010. The uplink signal can be provided to the signal amplifier 1022 via the first coaxial cable 1025 or other type of radio frequency connection operable to communicate radio frequency signals. The signal amplifier 1022 can include one or more cellular signal amplifiers for amplification and filtering. The uplink signal that has been amplified and filtered can be provided to the donor antenna 1026 via the second coaxial cable 1027 or other type of radio frequency connection operable to communicate radio frequency signals. The server antenna 1026 can communicate the uplink signal that has been amplified and filtered to the base station 1030.

In one example, the repeater 1020 can filter the uplink and downlink signals using any suitable analog or digital filtering technology including, but not limited to, surface acoustic wave (SAW) filters, bulk acoustic wave (BAW) filters, film bulk acoustic resonator (FBAR) filters, ceramic filters, waveguide filters or low-temperature co-fired ceramic (LTCC) filters.

In one example, the repeater 1020 can send uplink signals to a node and/or receive downlink signals from the node. The node can comprise a wireless wide area network (WWAN) access point (AP), a base station (BS), an evolved Node B (eNB), a baseband unit (BBU), a remote radio head (RRH), a remote radio equipment (RRE), a relay station (RS), a radio equipment (RE), a remote radio unit (RRU), a central processing module (CPM), or another type of WWAN access point.

In one example, the repeater 1020 can include a battery to provide power to various components, such as the signal amplifier 1022, the server antenna 1024 and the donor antenna 1026. The battery can also power the wireless device 1010 (e.g., phone or tablet). Alternatively, the repeater 1020 can receive power from the wireless device 1010.

In one configuration, the repeater 1020, also referred to as a signal booster, can be a Federal Communications Commission (FCC)-compatible consumer repeater. As a non-limiting example, the repeater 1020 can be compatible with FCC Part 20 or 47 Code of Federal Regulations (C.F.R.) Part 20.21 (Mar. 21, 2013). In addition, the handheld booster can operate on the frequencies used for the provision of subscriber-based services under parts 22

(Cellular), 24 (Broadband PCS), 27 (AWS-1, 700 megahertz (MHz) Lower A-E Blocks, and 700 MHz Upper C Block), and 90 (Specialized Mobile Radio) of 47 C.F.R. The repeater 1020 can be configured to automatically self-monitor its operation to ensure compliance with applicable noise and gain limits. The repeater 1020 can either self-correct or shut down automatically if the repeater's operations violate the regulations defined in 47 CFR Part 20.21. While a repeater that is compatible with FCC regulations is provided as an example, it is not intended to be limiting. The repeater can be configured to be compatible with other governmental regulations based on the location where the repeater is configured to operate.

In one configuration, the repeater 1020 can improve the wireless connection between the wireless device 1010 and the base station 1030 (e.g., cell tower) or another type of wireless wide area network (WWAN) access point (AP) by amplifying desired signals relative to a noise floor. The repeater 1020 can boost signals for cellular standards, such as the Third Generation Partnership Project (3GPP) Evolved Universal Mobile Telecommunications System (UMTS) Terrestrial Radio Access (E-UTRA) Release 8, 9, 10, 11, 12, 13, 14, 15, 16, 17, or 18, or 3GPP 5G Release 15, 16, 17 or 18. In one configuration, the repeater 1020 can boost signals for 3GPP E-UTRA Release 18.0.0 (January 2023) or other desired releases. The repeater 1020 can boost signals from the 3GPP Technical Specification (TS) 36.101 (Release 18 Jan. 2023) bands, referred to as E-UTRA frequency bands. For example, the repeater 1020 can be a multi-band signal booster configured to boost signals from selected E-UTRA and 5G frequency bands, such as bands: 2, 4, 5, 12, 13, 17, 25, and 26. In addition, the repeater 1020 can be configured to boost selected frequency bands based on the country or region in which the repeater is used, including any of bands 1-88 and 103 or other bands, as disclosed in 3GPP TS 36.104 V18.0.0 (January 2023), and depicted in Table 1. The repeater 1020 can be configured to meet the 3GPP TS 36.106 V17.0.0 (April 2022) and 38.106 V17.3.0 (January 2023) specification requirements.

TABLE 1

| | Uplink (UL) | Downlink (DL) | |
|---|---|---|---|
| | operating band | operating band | |
| E-UTRA | BS receive | BS transmit | |
| Operating | UE transmit | UE receive | Duplex |
| Band | F_{UL}_{_{—}}_{low}-F_{UL}_{_{—}}_{high} | F_{DL}_{_{—}}_{low}-F_{DL}_{_{—}}_{high} | Mode |
| 1 | 1920 MHz-1980 MHz | 2110 MHz-2170 MHz | FDD |
| 2 | 1850 MHz-1910 MHz | 1930 MHz-1990 MHz | FDD |
| 3 | 1710 MHz-1785 MHz | 1805 MHz-1880 MHz | FDD |
| 4 | 1710 MHz-1755 MHz | 2110 MHz-2155 MHz | FDD |
| 5 | 824 MHz-849 MHz | 869 MHz-894 MHz | FDD |
| 6¹ | 830 MHz-840 MHz | 875 MHz-885 MHz | FDD |
| 7 | 2500 MHz-2570 MHz | 2620 MHz-2690 MHz | FDD |
| 8 | 880 MHz-915 MHz | 925 MHz-960 MHz | FDD |
| 9 | 1749.9 MHz-1784.9 MHz | 1844.9 MHz-1879.9 MHz | FDD |
| 10 | 1710 MHz-1770 MHz | 2110 MHz-2170 MHz | FDD |
| 11 | 1427.9 MHz-1447.9 MHz | 1475.9 MHz-1495.9 MHz | FDD |
| 12 | 699 MHz-716 MHz | 729 MHz-746 MHz | FDD |
| 13 | 777 MHz-787 MHz | 746 MHz-756 MHz | FDD |
| 14 | 788 MHz-798 MHz | 758 MHz-768 MHz | FDD |
| 15 | Reserved | Reserved | FDD |
| 16 | Reserved | Reserved | FDD |
| 17 | 704 MHz-716 MHz | 734 MHz-746 MHz | FDD |
| 18 | 815 MHz-830 MHz | 860 MHz-875 MHz | FDD |
| 19 | 830 MHz-845 MHz | 875 MHz-890 MHz | FDD |
| 20 | 832 MHz-862 MHz | 791 MHz-821 MHz | FDD |
| 21 | 1447.9 MHz-1462.9 MHz | 1495.9 MHz-1510.9 MHz | FDD |
| 22 | 3410 MHz-3490 MHz | 3510 MHz-3590 MHz | FDD |
| 23¹ | 2000 MHz-2020 MHz | 2180 MHz-2200 MHz | FDD |
| 24¹⁷ | 1626.5 MHz-1660.5 MHz | 1525 MHz-1559 MHz | FDD |
| 25 | 1850 MHz-1915 MHz | 1930 MHz-1995 MHz | FDD |
| 26 | 814 MHz-849 MHz | 859 MHz-894 MHz | FDD |
| 27 | 807 MHz-824 MHz | 852 MHz-869 MHz | FDD |
| 28 | 703 MHz-748 MHz | 758 MHz-803 MHz | FDD |
| 29 | N/A | 717 MHz-728 MHz | FDD² |
| 30¹⁵ | 2305 MHz-2315 MHz | 2350 MHz-2360 MHz | FDD |
| 31 | 452.5 MHz-457.5 MHz | 462.5 MHz-467.5 MHz | FDD |
| 32 | N/A | 1452 MHz-1496 MHz | FDD² |
| 33 | 1900 MHz-1920 MHz | 1900 MHz-1920 MHz | TDD |
| 34 | 2010 MHz-2025 MHz | 2010 MHz-2025 MHz | TDD |
| 35 | 1850 MHz-1910 MHz | 1850 MHz-1910 MHz | TDD |
| 36 | 1930 MHz-1990 MHz | 1930 MHz-1990 MHz | TDD |
| 37 | 1910 MHz-1930 MHz | 1910 MHz-1930 MHz | TDD |
| 38 | 2570 MHz-2620 MHz | 2570 MHz-2620 MHz | TDD |
| 39 | 1880 MHz-1920 MHz | 1880 MHz-1920 MHz | TDD |
| 40 | 2300 MHz-2400 MHz | 2300 MHz-2400 MHz | TDD |
| 41 | 2496 MHz-2690 MHz | 2496 MHz-2690 MHz | TDD |
| 42 | 3400 MHz-3600 MHz | 3400 MHz-3600 MHz | TDD |
| 43 | 3600 MHz-3800 MHz | 3600 MHz-3800 MHz | TDD |
| 44 | 703 MHz-803 MHz | 703 MHz-803 MHz | TDD |
| 45 | 1447 MHz-1467 MHz | 1447 MHz-1467 MHz | TDD |
| 46 | 5150 MHz-5925 MHz | 5150 MHz-5925 MHz | TDD⁸ |
| 47 | 5855 MHz-5925 MHz | 5855 MHz-5925 MHz | TDD¹¹ |
| 48 | 3550 MHz-3700 MHz | 3550 MHz-3700 MHz | TDD |
| 49 | 3550 MHz-3700 MHz | 3550 MHz-3700 MHz | TDD¹⁶ |
| 50 | 1432 MHz-1517 MHz | 1432 MHz-1517 MHz | TDD¹³ |
| 51 | 1427 MHz-1432 MHz | 1427 MHz-1432 MHz | TDD¹³ |
| 52 | 3300 MHz-3400 MHz | 3300 MHz-3400 MHz | TDD |
| 53 | 2483.5 MHz-2495 MHz | 2483.5 MHz-2495 MHz | TDD |
| 54 | 1670 MHz-1675 MHz | 1670 MHz-1675 MHz | TDD |
| . . . | | | |
| 64 | Reserved | | |
| 65 | 1920 MHz-2010 MHz | 2110 MHz-2200 MHz | FDD |
| 66 | 1710 MHz-1780 MHz | 2110 MHz-2200 MHz | FDD⁴ |
| 67 | N/A | 738 MHz-758 MHz | FDD² |
| 68 | 698 MHz-728 MHz | 753 MHz-783 MHz | FDD |
| 69 | N/A | 2570 MHz-2620 MHz | FDD² |
| 70 | 1695 MHz-1710 MHz | 1995 MHz-2020 MHz | FDD¹⁰ |
| 71 | 663 MHz-698 MHz | 617 MHz-652 MHz | FDD |
| 72 | 451 MHz-456 MHz | 461 MHz-466 MHz | FDD |
| 73 | 450 MHz-455 MHz | 460 MHz-465 MHz | FDD |
| 74 | 1427 MHz-1470 MHz | 1475 MHz-1518 MHz | FDD |
| 75 | N/A | 1432 MHz-1517 MHz | FDD² |
| 76 | N/A | 1427 MHz-1432 MHz | FDD² |
| 85 | 698 MHz-716 MHz | 728 MHz-746 MHz | FDD |
| 87 | 410 MHz-415 MHz | 420 MHz-425 MHz | FDD |
| 88 | 412 MHz-417 MHz | 422 MHz-427 MHz | FDD |
| 103¹⁸ | 787 MHz-788 MHz | 757 MHz-758 MHz | FDD |

NOTE¹:
Band 6, 23 is not applicable
NOTE²:
Restricted to E-UTRA operation when carrier aggregation is configured. The downlink operating band is paired with the uplink operating band (external) of the carrier aggregation configuration that is supporting the configured Pcell.
NOTE 3:
A UE that complies with the E-UTRA Band 65 minimum requirements in this specification shall also comply with the E-UTRA Band 1 minimum requirements.
NOTE⁴:
The range 2180-2200 MHz of the DL operating band is restricted to E-UTRA operation when carrier aggregation is configured.
NOTE 5:
A UE that supports E-UTRA Band 66 shall receive in the entire DL operating band
NOTE 6:
A UE that supports E-UTRA Band 66 and CA operation in any CA band shall also comply with the minimum requirements specified for the DL CA configurations CA_66B, CA_66C and CA_66A-66A.
NOTE 7:
A UE that complies with the E-UTRA Band 66 minimum requirements in this specification shall also comply with the E-UTRA Band 4 minimum requirements.
NOTE⁸:
This band is an unlicensed band restricted to licensed-assisted operation using Frame Structure Type 3
NOTE 9:
In this version of the specification, restricted to E-UTRA DL operation when carrier aggregation is configured.
NOTE¹⁰:
The range 2010-2020 MHz of the DL operating band is restricted to E-UTRA operation when carrier aggregation is configured and TX-RX separation is 300 MHz. The range 2005-2020 MHz of the DL operating band is restricted to E-UTRA operation when carrier aggregation is configured and TX-RX separation is 295 MHz.
NOTE¹¹:
This band is unlicensed band used for V2X communication. There is no expected network deployment in this band so Frame Structure Type 1 is used.
NOTE 12:
A UE that complies with the E-UTRA Band 74 minimum requirements in this specification shall also comply with the E-UTRA Band 11 and Band 21 minimum requirements.
NOTE¹³:
UE that complies with the E-UTRA Band 50 minimum requirements in this specification shall also comply with the E-UTRA Band 51 minimum requirements.
NOTE 14:
A UE that complies with the E-UTRA Band 75 minimum requirements in this specification shall also comply with the E-UTRA Band 76 minimum requirements.
NOTE¹⁵:
Uplink transmission is not allowed at this band for UE with external vehicle-mounted antennas.
NOTE¹⁶:
This band is restricted to licensed-assisted operation using Frame Structure Type 3
NOTE¹⁷:
DL operation in this band is restricted to 1526-1536 MHz and UL operation is restricted to 1627.5-1637.5 MHz and 1646.5-1656.5 MHz.
NOTE¹⁸:
This band is restricted to NB-IoT operation only

In another configuration, the repeater 330 can boost signals from the 3GPP Technical Specification (TS) 38.101 (Release 18.0.0 January 2023) bands or 5G frequency bands. In addition, the repeater 330 can boost selected frequency bands based on the country or region in which the repeater is used, including any of the 5G frequency bands n1-n105 in Frequency Range 1 (FR1), and n257-n263, and non-terrestrial bands n255 and n256 or other bands, as disclosed in 3GPP TS 38.101-1 V18.0.0 (January 2023) and TS 38.101-2 V18.0.0 (January 2023), and depicted in Table 2 and Table 3:

TABLE 2

| | Uplink (UL) | Downlink (DL) | |
|---|---|---|---|
| | operating band | operating band | |
| NR | BS receive/ | BS transmit/ | |
| operating | UE transmit | UE receive | Duplex |
| band | F_{UL}_{_{—}}_{low}-F_{UL}_{_{—}}_{high} | F_{DL}_{_{—}}_{low}-F_{DL}_{_{—}}_{high} | Mode |
| n1 | 1920 MHz-1980 MHz | 2110 MHz-2170 MHz | FDD |
| n2 | 1850 MHz-1910 MHz | 1930 MHz-1990 MHz | FDD |
| n3 | 1710 MHz-1785 MHz | 1805 MHz-1880 MHz | FDD |
| n5 | 824 MHz-849 MHz | 869 MHz-894 MHz | FDD |
| n7 | 2500 MHz-2570 MHz | 2620 MHz-2690 MHz | FDD |
| n8 | 880 MHz-915 MHz | 925 MHz-960 MHz | FDD |
| n12 | 699 MHz-716 MHz | 729 MHz-746 MHz | FDD |
| n13 | 777 MHz-787 MHz | 746 MHz-756 MHz | FDD |
| n14 | 788 MHz-798 MHz | 758 MHz-768 MHz | FDD |
| n18 | 815 MHz-830 MHz | 860 MHz-875 MHz | FDD |
| n20 | 832 MHz-862 MHz | 791 MHz-821 MHz | FDD |
| n24¹⁶ | 1626.5 MHz-1660.5 MHz | 1525 MHz-1559 MHz | FDD |
| n25 | 1850 MHz-1915 MHz | 1930 MHz-1995 MHz | FDD |
| n26 | 814 MHz-849 MHz | 859 MHz-894 MHz | FDD |
| n28 | 703 MHz-748 MHz | 758 MHz-803 MHz | FDD |
| n29 | N/A | 717 MHz-728 MHz | SDL |
| n30³ | 2305 MHz-2315 MHz | 2350 MHz-2360 MHz | FDD |
| n34 | 2010 MHz-2025 MHz | 2010 MHz-2025 MHz | TDD |
| n38¹⁰ | 2570 MHz-2620 MHz | 2570 MHz-2620 MHz | TDD |
| n39 | 1880 MHz-1920 MHz | 1880 MHz-1920 MHz | TDD |
| n40 | 2300 MHz-2400 MHz | 2300 MHz-2400 MHz | TDD |
| n41 | 2496 MHz-2690 MHz | 2496 MHz-2690 MHz | TDD |
| n46 | 5150 MHz-5925 MHz | 5150 MHz-5925 MHz | TDD¹³ |
| n47¹¹ | 5855 MHz-5925 MHz | 5855 MHz-5925 MHz | TDD |
| n48 | 3550 MHz-3700 MHz | 3550 MHz-3700 MHz | TDD |
| n50 | 1432 MHz-1517 MHz | 1432 MHz-1517 MHz | TDD¹ |
| n51 | 1427 MHz-1432 MHz | 1427 MHz-1432 MHz | TDD |
| n53 | 2483.5 MHz-2495 MHz | 2483.5 MHz-2495 MHz | TDD |
| n65 | 1920 MHz-2010 MHz | 2110 MHz-2200 MHz | FDD⁴ |
| n66 | 1710 MHz-1780 MHz | 2110 MHz-2200 MHz | FDD |
| n67 | N/A | 738 MHz-758 MHz | SDL |
| n70 | 1695 MHz-1710 MHz | 1995 MHz-2020 MHz | FDD |
| n71 | 663 MHz-698 MHz | 617 MHz-652 MHz | FDD |
| n74 | 1427 MHz-1470 MHz | 1475 MHz-1518 MHz | FDD |
| n75 | N/A | 1432 MHz-1517 MHz | SDL |
| n76 | N/A | 1427 MHz-1432 MHz | SDL |
| n77¹² | 3300 MHz-4200 MHz | 3300 MHz-4200 MHz | TDD |
| n78 | 3300 MHz-3800 MHz | 3300 MHz-3800 MHz | TDD |
| n79¹⁷ | 4400 MHz-5000 MHz | 4400 MHz-5000 MHz | TDD |
| n80 | 1710 MHz-1785 MHz | N/A | SUL |
| n81 | 880 MHz-915 MHz | N/A | SUL |
| n82 | 832 MHz-862 MHz | N/A | SUL |
| n83 | 703 MHz-748 MHz | N/A | SUL |
| n84 | 1920 MHz-1980 MHz | N/A | SUL |
| n85 | 698 MHz-716 MHz | 728 MHz-746 MHz | FDD |
| n86 | 1710 MHz-1780 MHz | N/A | SUL |
| n89 | 824 MHz-849 MHz | N/A | SUL |
| n90 | 2496 MHz-2690 MHz | 2496 MHz-2690 MHz | TDD⁵ |
| n91 | 832 MHz-862 MHz | 1427 MHz-1432 MHz | FDD⁹ |
| n92 | 832 MHz-862 MHz | 1432 MHz-1517 MHz | FDD⁹ |
| n93 | 880 MHz-915 MHz | 1427 MHz-1432 MHz | FDD⁹ |
| n94 | 880 MHz-915 MHz | 1432 MHz-1517 MHz | FDD⁹ |
| n95⁸ | 2010 MHz-2025 MHz | N/A | SUL |
| n96¹⁴ | 5925 MHz-7125 MHz | 5925 MHz-7125 MHz | TDD¹³ |
| n97¹⁵ | 2300 MHz-2400 MHz | N/A | SUL |
| n98¹⁵ | 1880 MHz-1920 MHz | N/A | SUL |
| n99¹⁶ | 1626.5 MHz-1660.5 MHz | N/A | SUL |
| n100 | 874.4 MHz-880 MHz | 919.4 MHz-925 MHz | FDD |
| n101 | 1900 MHz-1910 MHz | 1900 MHz-1910 MHz | TDD |
| n102¹⁴ | 5925 MHz-6425 MHz | 5925 MHz-6425 MHz | TDD¹³ |
| n104^{17,18} | 6425 MHz-7125 MHz | 6425 MHz-7125 MHz | TDD |
| n105 | 663 MHz-703 MHz | 612 MHz-652 MHz | FDD |

NOTE¹:
UE that complies with the NR Band n50 minimum requirements in this specification shall also comply with the NR Band n51 minimum requirements.
NOTE 2:
UE that complies with the NR Band n75 minimum requirements in this specification shall also comply with the NR Band n76 minimum requirements.
NOTE³:
Uplink transmission is not allowed at this band for UE with external vehicle-mounted antennas.
NOTE⁴:
A UE that complies with the NR Band n65 minimum requirements in this specification shall also comply with the NR Band n1 minimum requirements.
NOTE⁵:
Unless otherwise stated, the applicability of requirements for Band n90 is in accordance with that for Band n41; a UE supporting Band n90 shall meet the requirements for Band n41. A UE supporting Band n90 shall also support band n41.
NOTE 6:
A UE that supports NR Band n66 shall receive in the entire DL operating band.
NOTE 7:
A UE that supports NR Band n66 and CA operation in any CA band shall also comply with the minimum requirements specified for the DL CA configurations CA_n66B and CA_n66(2A) in the current version of the specification.
NOTE⁸:
This band is applicable in China only.
NOTE⁹:
Variable duplex operation does not enable dynamic variable duplex configuration by the network, and is used such that DL and UL frequency ranges are supported independently in any valid frequency range for the band.
NOTE¹⁰:
When this band is used for V2X SL service, the band is exclusively used for NR V2X in particular regions.
NOTE¹¹:
This band is unlicensed band used for V2X service. There is no expected network deployment in this band.
NOTE¹²:
In the USA this band is restricted to 3450-3550 MHz and 3700-3980 MHz. In Canada this band is restricted to 3450-3650 MHz and 3650-3980 MHz.
NOTE¹³:
This band is restricted to operation with shared spectrum channel access as defined in 37.213.
NOTE¹⁴:
This band is applicable only in countries/regions designating this band for shared-spectrum access use subject to country-specific conditions.
NOTE¹⁵:
The requirements for this band are applicable only where no other NR or E-UTRA TDD operating band(s) are used within the frequency range of this band in the same geographical area. For scenarios where other NR or E-UTRA TDD operating band(s) are used within the frequency range of this band in the same geographical area, special co-existence requirements may apply that are not covered by the 3GPP specifications.
NOTE¹⁶:
DL operation in this band is restricted to 1526-1536 MHz and UL operation is restricted to 1627.5-1637.5 MHz and 1646.5-1656.5 MHz.
NOTE¹⁷:
For this band, CORESET#0 values from Table 13-5 or Table 13-6 in [8, TS 38.213] are applied regardless of the minimum channel bandwidth.
NOTE¹⁸:
[This band is applicable only to RCC countries in accordance with RCC Recommendation 1/2]

TABLE 3

| | Uplink (UL) | Downlink (DL) | |
|---|---|---|---|
| | operating band | operating band | |
| | BS receive | BS transmit | |
| Operating | UE transmit | UE receive | Duplex |
| Band | F_{UL}_{_{—}}_{low}-F_{UL}_{_{—}}_{high} | F_{DL}_{_{—}}_{low}-F_{DL}_{_{—}}_{high} | Mode |
| n257 | 26500 MHz-29500 MHz | 26500 MHz-29500 MHz | TDD |
| n258 | 24250 MHz-27500 MHz | 24250 MHz-27500 MHz | TDD |
| n259 | 39500 MHz-43500 MHz | 39500 MHz-43500 MHz | TDD |
| n260 | 37000 MHz-40000 MHz | 37000 MHz-40000 MHz | TDD |
| n261 | 27500 MHz-28350 MHz | 27500 MHz-28350 MHz | TDD |
| n262 | 47200 MHz-48200 MHz | 47200 MHz-48200 MHz | TDD |
| n263 | 57000 MHz-71000 MHz | 57000 MHz-71000 MHz | TDD¹ |

NOTE¹:
This band is for unlicensed operation and subject to regional and/or country specific regulatory requirements.

The number of 3GPP LTE or 5G frequency bands and the level of signal improvement can vary based on a particular wireless device, cellular node, or location. Additional domestic and international frequencies can also be included to offer increased functionality. Selected models of the repeater 1020 can be configured to operate with selected frequency bands based on the location of use. In another example, the repeater 1020 can automatically sense from the wireless device 1010 or base station 1030 (or GPS, etc.) which frequencies are used, which can be a benefit for international travelers.

In one example, the repeater can be configured to transmit a downlink (DL) signal in a millimeter wave (mm Wave) frequency range, and transmit an uplink (UL) signal in a sub-6 gigahertz (GHz) frequency range. In this example, a mm Wave frequency range can be a frequency between 6 GHz and 300 GHz.

In one configuration, multiple repeaters can be used to amplify UL and DL signals. For example, a first repeater can be used to amplify UL signals and a second repeater can be used to amplify DL signals. In addition, different repeaters can be used to amplify different frequency ranges.

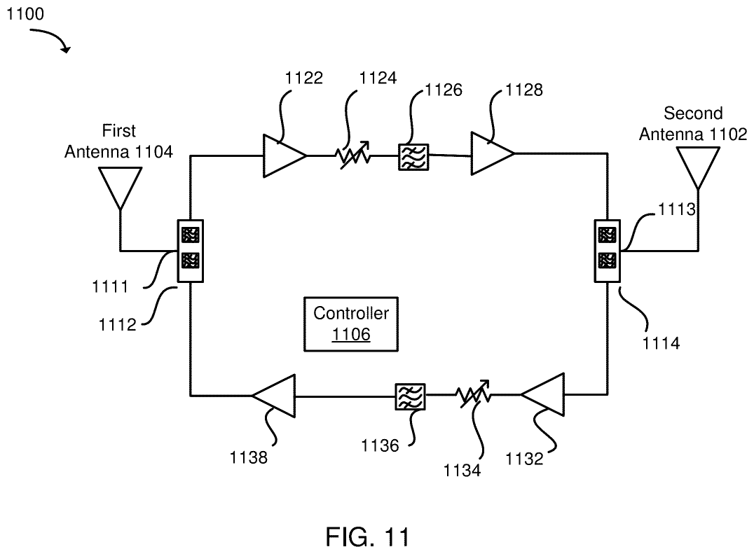

In an example, as illustrated in FIG. 11, a bi-directional full duplex frequency division duplex (FDD) repeater system can comprise a repeater 1100 connected to a first antenna 1104 and a second antenna 1102. The repeater 1100 can include a first antenna port 1111 that can be internally coupled to a second duplexer (or diplexer or multiplexer or circulator or splitter) 1114. The repeater 1100 can include a second antenna port 1113 that can also be coupled to a first duplexer (or diplexer or multiplexer or circulator or splitter) 1112. Between the two duplexers, 1114 and 1112, can be two paths: a first-direction path and a second-direction path. The first-direction path can comprise a low noise amplifier (LNA) 1122 with an input coupled to the first duplexer 1112, a variable attenuator 1124, such as a digital step attenuator, is coupled to an output of the LNA 1122, a filter 1126 coupled to the variable attenuator 1124, and a power amplifier (PA) 1128 coupled between the filter 1126 and the second duplexer 1114. The LNA 1122 can amplify a lower power signal with minimal degradation of the signal to noise ratio of the signal received at the first antenna 1104. The PA 1128 can adjust and amplify the power level by a desired amount to output a signal with a desired power level. The second-direction path can comprise an LNA 1132 with an input coupled to the second duplexer 1114, a variable attenuator 1134 coupled to an output of the LNA 1132, a filter 1136 coupled to the variable attenuator 1134, and a PA 1138 coupled between the filter 1136 and the first duplexer 1112. The first-direction path can be a downlink signal amplification path or an uplink signal amplification path. The second-direction path can be an uplink signal amplification path or a downlink signal amplification path. The repeater 1100 can also comprise a controller 1106. In one example, the controller 1106 can include one or more processors and memory.

In some embodiments, one or more of the power amplifiers 1128, 1138 can be wide-band RF amplifiers using cross-over diplexers, such as one or more of 300, 400, 500, 600, 700, 800 or 900 illustrated in the examples off FIGS. 3-9. However, the wideband RF amplifiers are not limited in use to power amplifiers. The wide-band RF amplifiers using cross-over diplexers can also be used as other types of RF signal amplification, such as low noise amplifiers (LNAs) 1122, 1132. The wide-band RF amplifiers using cross-over diplexers can provide a wide-band amplified RF signal with reduced harmonics and sub-harmonics relative to a power amplifier that does not use cross-over diplexers. The wide-band amplified RF signal output by the wide-band RF amplifiers using cross-over diplexers can be communicated to the first antenna 1104 and the second antenna 1102 for communication. The reduced harmonics can enable the UE and base station receiving the signals from the repeater 1100 to better receive and decode the wide-band amplified RF signal. This can enable communication between the repeater 1100 and the base station (i.e. 1030, FIG. 10) over greater distances and/or enable higher data rates to be communicated between the UE 1010 and the base station 1030 via the repeater 1020 using the wide-band amplified RF signals output by the wide-band RF amplifiers using cross-over diplexers.

In some embodiments the controller 1106 can adjust the gain of the first-direction path and/or the second-direction path based on wireless communication conditions. If included in the repeater 1100, the controller 1106 can be implemented by any suitable mechanism, such as a program, software, function, library, software as a service, analog or digital circuitry, or any combination thereof. The controller 1106 can also include a processor coupled to memory. The processor can include, for example, a microprocessor, microcontroller, digital signal processor (DSP), application specific integrated circuit (ASIC), a Field Programmable Gate Array (FPGA), or any other digital or analog circuitry configured to interpret and/or to execute program instructions and/or to process data. In some embodiments, the processor can interpret and/or execute program instructions and/or process data stored in the memory. The instructions can include instructions for adjusting the gain of the first path and/or the second path. For example, the adjustments can be based on radio frequency (RF) signal inputs.

The memory can include any suitable computer readable media configured to retain program instructions and/or data for a period of time. By way of example, and not limitation, such computer readable media can include tangible computer readable storage media including random access memory (RAM), read only memory (ROM), electrically erasable programmable read only memory (EEPROM), a compact disk (CD) ROM or other optical disk storage, magnetic disk storage or other magnetic storage devices, flash memory devices (e.g., solid state memory devices) or any other storage medium which can be used to carry or store desired program code in the form of computer executable instructions or data structures and which can be accessed by a general purpose or special purpose computer. Combinations of the above can also be included within the scope of computer readable media. Computer executable instructions can include, for example, instructions and data that cause a general-purpose computer, special purpose computer, or special purpose processing device to perform a certain function or group of functions.

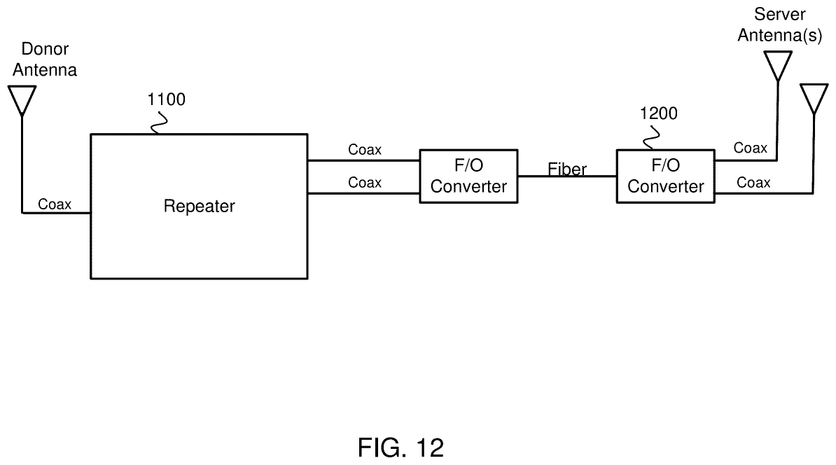

In another embodiment, a repeater, such as 1100, can be configured to communicate the wide-band amplified RF signals output by the wide-band RF amplifiers using cross-over diplexers, such as 100, 300, 400, 500, 600, 700, 800, or 900, illustrated in the examples of FIG. 1a and FIGS. 3-9, to a fiber/optic (F/O) converter in a distributed antenna system (DAS). The wide-band amplified RF signals an be converted to optical signals for communication over a fiber to another F/O converter that is configured to convert the optical signals to RF signals for communication to one or more server antenna(s), as illustrated in FIG. 12. In this example, the repeater 1100 and/or the F/O converter 1200 can include one or more wide-band RF amplifiers using cross-over diplexers, such as 300, 400, 500, 600, 700, 800, or 900 illustrated in the examples of FIGS. 3-9, to amplify a wide-band signal for transmission by the server antenna(s). For example, the F/O converter 1200 can include a wide-band RF amplifier using cross-over diplexers as an LNA or power amplifier.

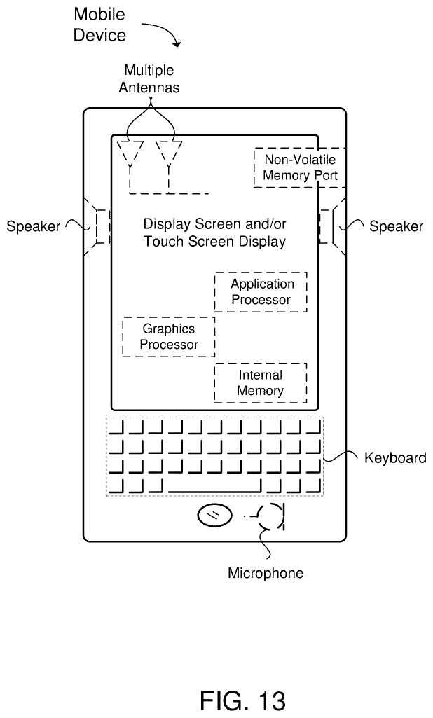

FIG. 13 provides an example illustration of the wireless device, such as a user equipment (UE), a mobile station (MS), a mobile communication device, a tablet, a handset, a wireless transceiver coupled to a processor, or other type of wireless device. The wireless device can include one or more antennas configured to communicate with a node or transmission station, such as an access point (AP), a base station (BS), an evolved Node B (eNB), a baseband unit (BBU), a remote radio head (RRH), a remote radio equipment (RRE), a relay station (RS), a radio equipment (RE), a remote radio unit (RRU), a central processing module (CPM), or other type of wireless wide area network (WWAN) access point. The wireless device can communicate using separate antennas for each wireless communication standard or shared antennas for multiple wireless communication standards. The wireless device can communicate in a wireless local area network (WLAN), a wireless personal area network (WPAN), and/or a WWAN.

FIG. 13 also provides an illustration of a microphone and one or more speakers that can be used for audio input and output from the wireless device. The display screen can be a liquid crystal display (LCD) screen, or other type of display screen such as an organic light emitting diode (OLED) display. The display screen can be configured as a touch screen. The touch screen can use capacitive, resistive, or another type of touch screen technology. An application processor and a graphics processor can be coupled to internal memory to provide processing and display capabilities. A non-volatile memory port can also be used to provide data input/output options to a user. The non-volatile memory port can also be used to expand the memory capabilities of the wireless device. A keyboard can be with the wireless device or wirelessly connected to the wireless device to provide additional user input. A virtual keyboard can also be provided using the touch screen.

Various techniques, or certain aspects or portions thereof, can take the form of program code (i.e., instructions) embodied in tangible media, such as floppy diskettes, compact disc-read-only memory (CD-ROMs), hard drives, non-transitory computer readable storage medium, or any other machine-readable storage medium wherein, when the program code is loaded into and executed by a machine, such as a computer, the machine becomes an apparatus for practicing the various techniques. Circuitry can include hardware, firmware, program code, executable code, computer instructions, and/or software. A non-transitory computer readable storage medium can be a computer readable storage medium that does not include signal. In the case of program code execution on programmable computers, the computing device can include a processor, a storage medium readable by the processor (including volatile and non-volatile memory and/or storage elements), at least one input device, and at least one output device. The volatile and non-volatile memory and/or storage elements can be a random-access memory (RAM), erasable programmable read only memory (EPROM), flash drive, optical drive, magnetic hard drive, solid state drive, or other medium for storing electronic data. The low energy fixed location node, wireless device, and location server can also include a transceiver module (i.e., transceiver), a counter module (i.e., counter), a processing module (i.e., processor), and/or a clock module (i.e., clock) or timer module (i.e., timer). One or more programs that can implement or utilize the various techniques described herein can use an application programming interface (API), reusable controls, and the like. Such programs can be implemented in a high level procedural or object-oriented programming language to communicate with a computer system. However, the program(s) can be implemented in assembly or machine language, if desired. In any case, the language can be a compiled or interpreted language, and combined with hardware implementations.

As used herein, the term processor can include general purpose processors, specialized processors such as VLSI, FPGAs, or other types of specialized processors, as well as base band processors used in transceivers to send, receive, and process wireless communications.

It should be understood that many of the functional units described in this specification have been labeled as modules, in order to more particularly emphasize their implementation independence. For example, a module can be implemented as a hardware circuit comprising custom very-large-scale integration (VLSI) circuits or gate arrays, off-the-shelf semiconductors such as logic chips, transistors, or other discrete components. A module can also be implemented in programmable hardware devices such as field programmable gate arrays, programmable array logic, programmable logic devices or the like.

In one example, multiple hardware circuits or multiple processors can be used to implement the functional units described in this specification. For example, a first hardware circuit or a first processor can be used to perform processing operations and a second hardware circuit or a second processor (e.g., a transceiver or a baseband processor) can be used to communicate with other entities. The first hardware circuit and the second hardware circuit can be incorporated into a single hardware circuit, or alternatively, the first hardware circuit and the second hardware circuit can be separate hardware circuits.

Modules can also be implemented in software for execution by various types of processors. An identified module of executable code can, for instance, comprise one or more physical or logical blocks of computer instructions, which can, for instance, be organized as an object, procedure, or function. Nevertheless, the executables of an identified module need not be physically located together, but can comprise disparate instructions stored in different locations which, when joined logically together, comprise the module and achieve the stated purpose for the module.

Indeed, a module of executable code can be a single instruction, or many instructions, and can even be distributed over several different code segments, among different programs, and across several memory devices. Similarly, operational data can be identified and illustrated herein within modules, and can be embodied in any suitable form and organized within any suitable type of data structure. The operational data can be collected as a single data set, or can be distributed over different locations including over different storage devices, and can exist, at least partially, merely as electronic signals on a system or network. The modules can be passive or active, including agents operable to perform desired functions.

Reference throughout this specification to “an example” or “exemplary” means that a particular feature, structure, or characteristic described in connection with the example is included in at least one embodiment of the present invention. Thus, appearances of the phrases “in an example” or the word “exemplary” in various places throughout this specification are not necessarily all referring to the same embodiment.

As used herein, a plurality of items, structural elements, compositional elements, and/or materials can be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention can be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics can be combined in any suitable manner in one or more embodiments. In the following description, numerous specific details are provided, such as examples of layouts, distances, network examples, etc., to provide a thorough understanding of embodiments of the invention. One skilled in the relevant art will recognize, however, that the invention can be practiced without one or more of the specific details, or with other methods, components, layouts, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

What is claimed is:

1. A wide-band radio frequency (RF) amplifier using cross-over diplexers, comprising:
a first port configured to receive a wide-band RF spectrum that includes RF signals within the wide-band RF spectrum;
a cross-over diplexer splitter coupled to the first port, wherein the cross-over diplexer splitter is configured to filter the wide-band RF spectrum into a low frequency (LF) pass-band with the RF signals including an LF signal within the LF pass-band and a high frequency (HF) pass-band with the RF signals including an HF signal within the HF pass-band, with the LF pass-band crossing the HF pass-band at a cross-over frequency;
an HF RF amplifier configured to amplify the HF signal within an HF amplification pass-band to form an amplified HF signal;
an LF RF amplifier configured to amplify the LF signal within an LF amplification pass-band to form an amplified LF signal;
wherein:
the HF amplification pass-band includes at least a portion of the LF pass-band that is beyond the cross-over frequency; and
the LF amplification pass-band includes at least a portion of the HF pass-band that is beyond the cross-over frequency; and
a cross-over diplexer combiner configured to combine the amplified HF signal and the amplified LF signal and output amplified RF signals in an wide-band RF spectrum.

2. The wide-band RF amplifier of claim 1, wherein the cross-over diplexer splitter is configured to filter the wide-band RF spectrum such that the LF signal and the RF signal each have a loss of approximately 3 decibels (dB) at the cross-over frequency relative to a signal power of the LF signal and the HF signal in the wide-band RF spectrum at an input of the cross-over diplexer splitter.

3. The wide-band RF amplifier of claim 1, further comprising one or more of:
an amplitude equalizer located between the cross-over diplexer splitter and the cross-over diplexer combiner to substantially equalize an amplitude of the LF signal and an amplitude of the HF signal at the cross-over frequency at an input to the cross-over diplexer combiner; and
a phase equalizer located between the cross-over diplexer splitter and the cross-over diplexer combiner to substantially equalize a phase of the amplified LF signal and a phase of the amplified HF signal at the cross-over frequency at the input to the cross-over diplexer combiner.

4. The wide-band RF amplifier of claim 3, wherein the amplitude equalizer is one or more of a fixed amplifier, a variable amplifier, a filter, a fixed attenuator, or a variable attenuator.

5. The wide-band RF amplifier of claim 3, wherein the phase equalizer is one or more of a delay line, a phase shifter, or a filter.

6. The wide-band RF amplifier of claim 1, wherein a bandwidth of the wide-band RF spectrum is greater than one octave.

7. The wide-band RF amplifier of claim 1, wherein a harmonic of the amplified LF signal is attenuated since the harmonic has a frequency that is greater than the cross-over frequency to enable the cross-over diplexer combiner to filter the harmonic with one of a low pass filter and a band pass filter.

8. The wide-band RF amplifier of claim 1, wherein a difference signal of the amplified HF signal and the amplified LF signal has a frequency that is less than the cross-over frequency to enable the cross-over diplexer combiner to filter the harmonic with one of a high pass filter and a band pass filter.

9. The wide-band RF amplifier of claim 1, wherein the cross-over diplexer splitter and the cross-over diplexer combiner are configured to split the wide-band RF spectrum into contiguous sub-bands to amplify the HF signal and the LF signal within a selected bandwidth of the wide-band RF spectrum without guard bands.

10. The wide-band RF amplifier of claim 1, wherein the HF signal and the LF signal are amplitude and phase balanced at the cross-over frequency.

11. The wide-band RF amplifier of claim 1, wherein the wide-band RF amplifier is configured to amplify the HF signal and the LF signal without an attenuation guard band at the cross-over frequency.

12. The wide-band RF amplifier of claim 1, wherein the HF pass-band and the LF pass-band are contiguous with no guard band between the HF pass-band and the LF pass-band.

13. The wide-band RF amplifier of claim 1, wherein the second port is configured to be coupled to and communicate the RF signals in the amplified RF wide-band spectrum to one or more of a radio frequency repeater, a distributed antenna system, or one or more antennas.

14. The wide-band RF amplifier of claim 1, wherein the second port is configured to be coupled to one or more of a wide-band optical distributed antenna system or a bidirectional amplifier that is configured to be communicatively coupled to an output of the diplexer combiner and receive the amplified RF wide-band spectrum with the reduced second harmonic distortion to enable the RF signals within the amplified RF wide-band spectrum to be amplified by or used by the wide-band optical distributed antenna system or the bidirectional amplifier with reduced harmonic distortion.

15. The wide-band RF amplifier of claim 1, wherein the wide-band RF amplifier is configured as a power amplifier for amplification of the wide-band RF input spectrum for transmission at an antenna.

16. The wide-band RF amplifier of claim 1, wherein the wide-band RF amplifier is configured as a low noise amplifier (LNA) to amplify the received wide-band RF spectrum.

17. A wide-band radio frequency (RF) amplifier with cross-over diplexers, comprising:
a first port configured to receive RF signals in an RF wide-band spectrum;
a first cross-over diplexer splitter communicatively coupled to the first port to receive the RF signals in the RF wide-band spectrum;
2n cross-over diplexer splitters communicatively coupled to an output of the first cross-over diplexer splitter, where n is a positive integer, wherein each of the 2n cross-over diplexer splitters are configured to receive a portion of the RF signals in the RF wide-band spectrum and filter the portion of the RF signals in the RF wide-band spectrum into a low frequency (LF) pass-band with the portion of the RF signals including an LF pass-band signal and a high frequency (HF) pass-band with the portion of the RF signals including an HF pass-band signal, and the LF pass-band crosses the HF pass-band at a cross-over frequency;
an HF RF amplifier coupled to an output of one or more of the 2n cross-over diplexer splitters and configured to amplify the HF signal within an HF amplification pass-band to form an amplified HF signal;
an LF RF amplifier coupled to an output of the one or more of the 2n cross-over diplexer splitters and configured to amplify the LF signal within an LF amplification pass-band to form an amplified LF signal;
wherein:
the HF amplification pass-band includes at least a portion of the LF pass-band that is beyond the cross-over frequency; and
the LF amplification pass-band includes at least a portion of the HF pass-band that is beyond the cross-over frequency;
2n cross-over diplexer combiners, wherein each of the cross-over diplexer combiners is coupled to an output of the HF RF amplifier and the LF RF amplifier of the one or more of the 2n cross-over diplexer splitters, respectively;
a final cross-over diplexer combiner configured to combine the amplified HF signals from the HF RF amplifiers that are coupled to the outputs of the one or more of the 2n cross-over diplexer splitters and the amplified LF signals from the LF RF amplifiers that are coupled to the outputs of the one or more of the 2n cross-over diplexer splitters and output amplified RF signals in the RF wide-band spectrum.

18. The wide-band RF amplifier of claim 17, wherein the first cross-over diplexer splitter is configured to filter the RF signals in the wide-band RF spectrum such that the LF signal and the HF signal each have a loss of approximately 3 decibels (dB) at the cross-over frequency relative to a signal power of the LF signal and the HF signal in the wide-band RF spectrum at an input of the cross-over diplexer splitter.

19. The wide-band RF amplifier of claim 17, further comprising one or more of:
an amplitude equalizer located between the first cross-over diplexer splitter and the final cross-over diplexer combiner to substantially equalize an amplitude of the amplified LF signal and an amplitude of the amplified HF signal at the cross-over frequency at an input to the final cross-over diplexer combiner; and
a phase equalizer located between the first cross-over diplexer splitter and the final cross-over diplexer combiner to substantially equalize a phase of the amplified LF signal and a phase of the amplified HF signal at the cross-over frequency at the input to the final cross-over diplexer combiner.

20. The wide-band RF amplifier of claim 19, wherein the amplitude equalizer is one or more of a fixed amplifier, a variable amplifier, a filter, a fixed attenuator, or a variable attenuator.

21. The wide-band RF amplifier of claim 19, wherein the phase equalizer is one or more of a delay line, a phase shifter, or a filter.

22. The wide-band RF amplifier of claim 17, wherein a bandwidth of the wide-band RF signal is greater than one octave.

23. The wide-band RF amplifier of claim 17, wherein a bandwidth of each of the LF pass-bands with the amplified LF signals is less than an octave to enable a harmonic of each of the amplified LF signals to be attenuated by one of a low pass filter or a band pass filter in the cross-over diplexer combiner since the harmonic has a frequency that is greater than the cross-over frequency to enable the cross-over diplexer combiner to filter the harmonic with one of the low pass filter and the band pass filter.

24. The wide-band RF amplifier of claim 17, wherein a difference signal of the amplified HF signal and the amplified LF signal has a frequency that is less than the cross-over frequency to enable the cross-over diplexer combiner to filter the harmonic with one of a high pass filter and a band pass filter.

25. The wide-band RF amplifier of claim 17, wherein the cross-over diplexer splitters are configured to split the RF signals in the wide-band RF spectrum into contiguous sub-bands to enable the cross-over diplexer combiners to combine the amplified LF signals within the LF pass-band with the amplified HF signals within the HF pass-band to form the amplified RF signals in the wide-band RF spectrum without guard bands between the LF pass-band of the amplified LF signals and the HF pass-band of the amplified HF signals.

26. The wide-band RF amplifier of claim 17, wherein the amplified HF signals and the amplified LF signals are one or more of amplitude balanced and phase balanced at the cross-over frequency.

27. The wide-band RF amplifier of claim 17, wherein the HF signals and the LF signals are amplified without an attenuation guard band at the cross-over frequency.

28. The wide-band RF amplifier of claim 17, wherein the HF pass-band and the LF pass-band are contiguous with no guard band between the HF signals and the LF signals output from each of the 2n cross-over diplexer splitters.

29. The wide-band RF amplifier of claim 17, wherein the second port is configured to be coupled to and communicate the RF signals in the wide-band RF spectrum to one or more of a radio frequency repeater, a distributed antenna system, or one or more antennas.

30. The wide-band RF amplifier of claim 17, wherein the wide-band RF amplifier is configured as a power amplifier for amplification of the RF signals in the wide-band RF spectrum for transmission at an antenna.

31. The wide-band RF amplifier of claim 17, wherein the wide-band RF amplifier is configured as a low noise amplifier (LNA) to amplify the RF signals in the wide-band RF spectrum.

32. A wide-band radio frequency (RF) amplifier using cross-over diplexers, comprising:
a first port configured to receive a wide-band RF spectrum that includes RF signals within the wide-band RF spectrum;
a cross-over diplexer splitter coupled to the first port, wherein the cross-over diplexer splitter is configured to filter the RF signals in the wide-band RF spectrum into a low frequency (LF) pass-band with the RF signals including an LF signal within the LF pass-band and a high frequency (HF) pass-band with the RF signals including an HF signal within the HF pass-band, with the LF pass-band crossing the HF pass-band at a cross-over frequency;
an HF RF amplifier configured to amplify the HF signal within an HF amplification pass-band to form an amplified HF signal;
an LF RF amplifier configured to amplify the LF signal within an LF amplification pass-band to form an amplified LF signal;
wherein:
the HF amplification pass-band includes at least a portion of the LF pass-band that is beyond the cross-over frequency; and
the LF amplification pass-band includes at least a portion of the HF pass-band that is beyond the cross-over frequency; and
the HF amplifier is configured to be communicatively coupled to a first antenna to transmit the amplified HF signal; and
the LF amplifier is configured to be communicatively coupled to a second antenna to transmit the amplified LF signal.

33. The wide-band RF amplifier of claim 32, wherein the cross-over diplexer splitter is configured to split the wide-band RF input spectrum into contiguous sub-bands.

34. The wide-band RF amplifier of claim 32, wherein the cross-over diplexer splitter is configured to filter the wide-band RF spectrum such that the LF signal and the HF signal each have a loss of approximately 3 decibels (dB) at the cross-over frequency relative to a signal power of the LF signal and the HF signal at an input of the cross-over diplexer splitter.

35. The wide-band RF amplifier of claim 32, wherein a bandwidth of the wide-band RF spectrum is greater than one octave.

36. The wide-band RF amplifier of claim 32, wherein a bandwidth of the HF pass-band is less than one octave and a bandwidth of the LF pass-band is less than one octave.
